(19) United States
(12) Patent Application Publication
(10) Pub. No.: US 2022/0344597 A1
(43) Pub. Date: Oct. 27, 2022

(54) ORGANIC ELECTROLUMINESCENT DEVICE

(71) Applicant: SOLUS ADVANCED MATERIALS CO., LTD., Iksan-si, Jeollabuk-do (KR)

(72) Inventors: Songie HAN, Yongin-si (KR); Hocheol PARK, Yongin-si (KR); Youngmo KIM, Yongin-si (KR); Seungeun JUNG, Yongin-si (KR); Geunhyeong KIM, Yongin-si (KR); Hyobum SONG, Yongin-si (KR); Taehyung KIM, Yongin-si (KR)

(73) Assignee: SOLUS ADVANCED MATERIALS CO., LTD., Iksan-si, Jeollabuk-do (KR)

(21) Appl. No.: 17/760,606

(22) PCT Filed: Aug. 27, 2020
(86) PCT No.: PCT/KR2020/011490

§ 371 Date: Mar. 15, 2022

(30) Foreign Application Priority Data
Sep. 16, 2019 (KR) 10-2019-0113646

(51) Int. Cl. H01L 51/00; C09K 11/06

(52) U.S. Cl. CPC H01L 51/0072; C09K 11/06; H01L 51/0067; H01L 51/0071; H01L 51/0052; H01L 51/0073; H01L 51/0054; H01L 51/0058; H01L 2251/552; H01L 2251/5384; H01L 51/5004

(57) ABSTRACT

An organic electroluminescent device is disclosed. The organic electroluminescent device includes a light-emitting layer that contains a plurality of hosts and dopants, where one of the plurality of hosts includes the same material as in an electron transport auxiliary layer in an electron transport region, whereby the organic electroluminescent device simultaneously exhibits effects such as low driving voltage, high luminous efficiency, and a long lifespan.

### TECHNICAL FIELD

The present invention relates to an organic electroluminescent device simultaneously exhibiting effects such as high luminous efficiency, low driving voltage, and a long lifespan.

### BACKGROUND ART

In general, in organic electroluminescent devices (“organic EL devices”), when current or voltage is applied to two electrodes, holes are injected into an organic layer at an anode, and electrons are injected into an organic layer at a cathode. When the injected holes and electrons meet, an exciton is formed, and light is emitted when the exciton falls to the ground state.

Such organic EL devices may be classified, according to an electron spin type of the formed excitons, into fluorescent EL devices in which singlet excitons contribute to light emission and phosphorescent EL devices in which triplet excitons contribute to light-emission.

Theoretically, fluorescent EL devices may have an internal quantum efficiency of up to 25%, depending on the generation ratio, whereas phosphorescent EL devices may have an internal quantum efficiency of up to 100%. In the case of phosphorescence, high internal quantum efficiency may be obtained because triplets and singlets are involved in internal quantum efficiency, but in the case of fluorescence, only singlet transition occurs, so the maximum internal quantum efficiency is about a quarter of that of phosphorescence. As such, the phosphorescent EL devices have theoretically higher luminous efficiency than the fluorescence.

However, unlike green and red phosphorescent EL devices, blue phosphorescent EL devices have not been commercialized due to a low development level of phosphorescent dopants having deep blue color purity and high efficiency and hosts having a wide energy gap. Accordingly, blue fluorescent EL devices are in use instead of the blue phosphorescent EL devices.

However, the development of organic EL devices having high efficiency and a long lifespan is required in accordance with the recent trend of display enlargement and high resolution. In particular, the high resolution of the display may be realized when more pixels are formed in the same area. For this reason, the light-emitting area of the organic EL devices may decrease, and accordingly, the decrease in the light-emitting area serves as a cause of shortening the life of the organic EL devices.

Accordingly, various studies have been conducted to improve the characteristics of the organic EL device, but satisfactory results have not been obtained so far.

### DETAILED DESCRIPTION OF THE INVENTION

### Technical Objectives

The present invention is directed to an organic electroluminescent device in which a light-emitting layer includes a plurality of hosts and dopants, where one of the plurality of hosts includes the same material as in an electron transport auxiliary layer, whereby the organic electroluminescent device exhibits effects such as low driving voltage, high luminous efficiency, and a long lifespan.

### Technical Solution to the Problem

The present invention provides an organic electroluminescent device including: an anode; a cathode disposed opposing the anode; and an organic layer disposed between the anode and the cathode and comprising a hole transport region, a light-emitting layer, and an electron transport region sequentially disposed on the anode, wherein the electron transport region comprises an electron transport auxiliary layer, an electron transport layer and an electron injection layer sequentially disposed on the light-emitting layer, the light-emitting layer comprises a plurality of hosts and dopants, and one of the plurality of hosts comprises a material the same as a material of the electron transport auxiliary layer.

### Effects of the Invention

The present invention provides an organic electroluminescent device in which a light-emitting layer includes a plurality of hosts and dopants, where one of the plurality of hosts includes the same material as in an electron transport auxiliary layer, whereby the organic electroluminescent device exhibits effects such as low driving voltage, high luminous efficiency, and a long lifespan.

The present invention further provides a display panel with improved performance and lifespan by applying the organic electroluminescent device of the present invention to the display panel.

### BRIEF DESCRIPTION OF DRAWINGS

FIG. 1 is a cross-sectional view illustrating a structure of an organic electroluminescent (“EL”) device according to an embodiment of the present invention.

FIG. 2 is a cross-sectional view illustrating a structure of an organic EL device according to another embodiment of the present invention.

FIG. 3 is a graph illustrating relationship of a highest occupied molecular orbital (“HOMO”) energy level between a light-emitting layer and an electron transport auxiliary layer according to an embodiment of the present invention.

FIG. 4 is a graph illustrating relationship of a lowest unoccupied molecular orbital (“LUMO”) energy level between a light-emitting layer, an electron transport auxiliary layer, and an electron transport layer according to an embodiment of the present invention.

### REFERENTIAL NUMERAL

100: anode
200: cathode
300: organic layer
310: hole transport region
311: hole injection layer
312: hole transport layer
313: hole transport auxiliary layer
320: light-emitting layer
330: electron transport region
331: electron transport auxiliary layer
332: electron transport layer
333: electron injection layer

### MODES FOR CARRYING OUT THE INVENTION

Advantages and features of the present invention and methods for achieving them will become apparent with reference to embodiments described below in detail in conjunction with the accompanying drawings. However, the present invention is not limited to the embodiments disclosed below but may be implemented in various different forms, and it is to be understood that the present embodiments are merely provided to make the disclosure of the present invention complete and to fully convey the scope of the present invention to those of ordinary skill in the art, and the present invention is defined only by the scope of the claims. Thus, in some embodiments, well-known process steps, well-known device structures and well-known techniques are not described in detail in order to avoid obscuring the present invention. Like reference numerals refer to like elements throughout the specification.

Unless otherwise defined, all terms used in the present specification (including technical and scientific terms) may be used with meanings that may be commonly understood by those skilled in the art. In addition, the terms defined in the commonly used dictionaries are not ideally or excessively interpreted, unless they are specifically defined clearly.

An organic electroluminescent (“EL”) device according to the present invention includes: an anode; a cathode disposed opposing the anode; and one or more organic layers disposed between the anode and the cathode and including a hole transport region, a light-emitting layer, and an electron transport region, where the same material as in an electron transport auxiliary layer in the electron transport region is used in one of a plurality of hosts in the light-emitting layer. Accordingly, the organic EL device of the present invention may have characteristics such as a low driving voltage, a high luminous efficiency and a long lifespan.

Specifically, in the organic EL device of the present invention, the light-emitting layer includes a plurality of hosts, for example, a first host and a second host different from each other, to prevent reverse transfer phenomenon in which exciton transferred from the host to the dopant is transferred back to the host, while improving recombination efficiency of the holes and electrons.

In such a case, an electron transport auxiliary layer may be disposed between the light-emitting layer and the electron transport layer, and one of the plurality of hosts may include a material the same as a material of the electron transport auxiliary layer, such that an electron injection barrier between the light-emitting layer and the electron transport layer may be lowered, and barrier-free effects between the light-emitting layer and the electron transport auxiliary layer may be exhibited, thereby allowing electrons injected from the electron transport layer to be smoothly supplied to the light-emitting layer through the electron transport auxiliary layer. Accordingly, in the organic EL device of the present invention, luminous efficiency may be enhanced, a driving voltage may be lowered, and lifespan characteristics may be significantly improved.

Hereinafter, embodiments of the organic EL device according to the present invention will be described with reference to the accompanying drawings. However, embodiment of the present invention may be modified into various other forms, and the scope of the present invention is not limited to the embodiments described below.

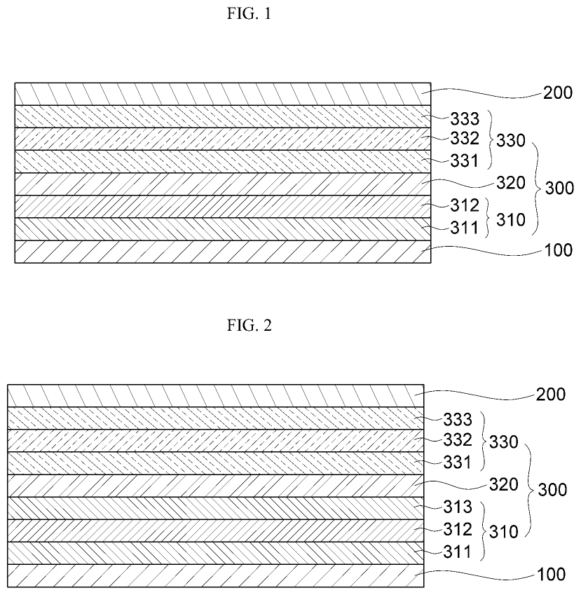

FIG. 1 is a cross-sectional view illustrating a structure of an organic electroluminescent (“EL”) device according to an embodiment of the present invention. FIG. 2 is a cross-sectional view illustrating a structure of an organic EL device according to another embodiment of the present invention.

Referring to FIGS. 1 and 2, the organic EL device sequentially includes an anode 100, one or more organic layers 300, and a cathode 200, and the organic layer 300 includes a hole transport region 310, a light-emitting layer 320, and an electron transport region 330.

Optionally, the organic EL device may further include a capping layer (not illustrated) disposed on the cathode 200.

Hereinafter, each structure of the organic EL device according to the present invention will be described in detail.

(1) Anode

The organic EL device of the present invention includes the anode 100. The anode 100 may be disposed on a substrate and electrically connected to a driving thin film transistor (“TFT”) to receive a driving current from the driving thin film transistor. Since the anode 100 includes or is formed of a material having a relatively high work function, it may inject holes into an adjacent one of the organic layers, that is, the hole transport region 310 (e.g., a hole injection layer 311).

A material for forming the anode is not particularly limited, and a conventional one known in the art may be used. Examples thereof may include metals, such as vanadium, chromium, copper, zinc, and gold; alloys thereof; metal oxides such as zinc oxide, indium oxide, indium tin oxide (ITO), and indium zinc oxide (IZO); combinations of metals and oxides such as ZnO:Al and SnO₂:Sb; conductive polymers such as polythiophene, poly(3-methylthiophene), poly[3,4-(ethylene-1,2-dioxy)thiophene] (PEDT), polypyrrole, and polyaniline; and carbon black, but embodiments are not limited thereto.

A method of preparing the anode is not particularly limited, and may be prepared through a conventional method known in the art. For example, the anode may be formed by coating the anode material on a substrate through a known thin film forming method such as a sputtering method, an ion plating method, a vacuum deposition method, or a spin coating method.

The substrate may be a plate-shaped member for supporting the organic EL device, and include, for example, a silicon wafer, quartz, a glass plate, a metal plate, a plastic film, and a sheet, but embodiments are not limited thereto.

(2) Cathode

In the organic EL device of the present invention, the cathode 200 is disposed opposing the anode, and specifically, disposed on the electron transport region 330. Since the cathode 200 includes or is formed of a material having a relatively low work function, it may inject electrons into an adjacent one of the organic layers, that is, the electron transport region 330 (e.g., an electron injection layer 333).

A material for forming the cathode is not particularly limited, and a conventional one known in the art may be used. Examples thereof may include metals, such as magnesium, calcium, sodium, potassium, titanium, indium, yttrium, lithium, gadolinium, aluminum, silver (Ag), tin, and lead; alloys thereof; and a multi-layer structure material such as LiF/Al or LiO₂/Al, but embodiments are not limited thereto.

A method of preparing the cathode is not particularly limited, and similar to the anode, the cathode may be prepared through a conventional method known in the art. For example, the cathode may be formed by coating the cathode material on the one or more organic layers 300, specifically on the electron transport region, for example, the electron injection layer 333, through the above-described thin film forming method.

(3) Organic Layer

In the organic EL device of the present invention, the one or more organic layers 300 are disposed between the anode 100 and the cathode 200.

The organic layer 300 includes the hole transport region 310, the light-emitting layer 320, and the electron transport region 330.

According to an embodiment, as illustrated in FIG. 1, the one or more organic layers 300 may include a hole injection layer 311, a hole transport layer 312, a hole transport auxiliary layer 313, a light-emitting layer 320, an electron transport auxiliary layer 331, an electron transport layer 332, and an electron injection layer 333 sequentially disposed on the anode 100.

According to another embodiment, as illustrated in FIG. 2, the one or more organic layers 300 may include a hole injection layer 311, a hole transport layer 312, a hole transport auxiliary layer 313, a light-emitting layer 320, an electron transport auxiliary layer 331, an electron transport layer 332, and an electron injection layer 333 sequentially disposed on the anode 100.

Hereinafter, each organic layer will be described.

1) Hole Transport Region

In the organic EL device 100 of the present invention, the hole transport region 310 is a portion of the organic layer 300 disposed on the anode 100, and serves to allow holes injected from the anode 100 to migrate into another adjacent one of the organic layers, specifically to the light-emitting layer 320. The hole transport region 310 may include at least one of the hole injection layer 311, the hole transport layer 312, and the hole transport auxiliary layer 313.

For example, as illustrated in FIG. 1, the hole transport region 310 may include the hole injection layer 311 and the hole transport layer 312 sequentially stacked on the anode 100.

As another example, as illustrated in FIG. 2, the hole transport region 310 may include the hole injection layer 311, the hole transport layer 312, and the hole transport auxiliary layer 313 sequentially stacked on the anode 100.

A material forming the hole injection layer 311 and the hole transport layer 312 of the present invention is not particularly limited as long as it has a low hole injection barrier and a high hole mobility, and any material for the hole injection/transport layer may be used without limitation. In such a case, respective materials for forming the hole injection layer 311 and the hole transport layer 312 may be the same or different from each other.

Specifically, the hole injection layer 311 may include a hole injection material known in the art. Non-limiting examples of the hole injection material may include phthalocyanine compounds such as copper phthalocyanine; DNTPD (N,N′-diphenyl-N,N′-bis-[4-(phenyl-m-tolyl-amino)-phenyl]-biphenyl-4,4′-diamine), m-MTDATA (4,4′,4″-tris(3-methylphenylphenylamino) triphenylamine), TDATA (4,4′4″-Tris(N,N-diphenylamino)triphenylamine), 2TNATA (4,4′,4″-tris{N,-(2-naphthyl)-N-phenylamino}-triphenylamine), PEDOT/PSS (poly(3,4-ethylenedioxythiophene)/poly(4-styrenesulfonate)), PANI/DBSA (polyaniline/dodecylbenzenesulfonic acid), PANI/CSA (polyaniline/Camphor sulfonicacid), PANI/PSS ((polyaniline)/poly(4-styrenesulfonate)), and the like, which may be used solely or in combination of two or more thereof.

The hole transport layer 312 includes a hole transport material known in the art. Non-limiting examples of the hole transport material may include carbazole-based derivatives such as N-phenylcarbazole and polyvinylcarbazole; fluorene-based derivatives; amine-based derivatives; triphenylamine-based derivatives such as TPD (N,N′-bis(3-methylphenyl)-N,N′-diphenyl-[1,1-biphenyl]-4,4′-diamine) and TCTA (4,4′,4″-tris(N-carbazolyl)triphenylamine); NPB (N,N′-di(1-naphthyl)-N,N′-diphenylbenzidine), TAPC (4,4′-cyclohexylidene bis[N,N-bis(4-methylphenyl)benzenamine]), and the like, which may be used solely or in combination of two or more thereof.

The hole transport auxiliary layer 313 may prevent electrons or excitons generated in the light-emitting layer 320 from diffusing (migrating) into the hole transport region 310. A material of the hole transport auxiliary layer 313 may be used without limitation as long as it has general hole transport properties known in the art, and may be, for example, the above-described hole transport material.

The hole transport region 310 may be formed through a conventional method known in the art. For example, there may be a vacuum deposition method, a spin coating method, a casting method, a Langmuir-Blodgett (LB) method, an inkjet printing method, a laser printing method, a laser induced thermal imaging (LITI) method, and the like, but embodiments are not limited thereto.

2) Light-Emitting Layer

In the organic EL device of the present invention, the light-emitting layer 320 is a portion of the organic layer 300 disposed between the anode 100 and the cathode 200, and specifically disposed on the hole transport region 320. Specifically, the light-emitting layer 320 may be disposed on the hole transport layer 312 or on the hole transport auxiliary layer 313 (see FIGS. 1 and 2). The light-emitting layer 320 is a layer in which holes and electrons injected from the anode and the cathode, respectively, are combined to form excitons, and a color of light emitted by the organic EL device may vary depending on the material forming the light-emitting layer 320.

The light-emitting layer 320 of the present invention includes a plurality of hosts and dopants. In such a case, one of the plurality of hosts is (e.g., is or includes) a material the same as (e.g., identical to) a material included in or forming the electron transport auxiliary layer (“electron transport auxiliary layer material”).

According to an embodiment, the plurality of hosts may include: a first host that is the same as the electron transport auxiliary layer material; and a second host different from the first host. As such, when one of the plurality of hosts is the same as the electron transport auxiliary layer material, barrier-free effects may be exhibited between the light-emitting layer and the electron transport auxiliary layer, thereby realizing a low driving voltage, a high luminous efficiency and a long lifespan of the device.

The first host of the present invention is a material the same as a material of the electron transport auxiliary layer. Specifically, the first host may be a compound including at least one of moieties represented by the following Chemical Formulas 1 and 2, more specifically, may be a compound represented by any one of the following Chemical Formulas 4 to 6, and more specifically, may be a compound represented by any one of the following Chemical Formulas A-1 to A-16. For example, the first host may be a compound represented by any one of the following Chemical Formulas B-1 to B-9. According to an embodiment, the first host of the present invention may be one of the following compounds 1 to 14. A detailed description of these compounds will be described below in a section of the electron transport auxiliary layer.

The second host of the present invention is a host different from the first host, any host known in the art may be used without particular limitation, and non-limiting examples thereof may include alkali metal complex compounds; alkaline earth metal complex compounds; or aromatic ring-fused derivatives. Specifically, examples of the second host may include aluminum complex compounds, beryllium complex compounds, iridium compounds, anthracene derivatives, pyrene derivatives, triphenylene derivatives, carbazole derivatives, dibenzofuran derivatives, dibenzothiophene derivatives, fluorene derivatives, nitrogen-containing heterocyclic derivatives, or a combination of one or more thereof which may enhance luminous efficiency and lifespan of the organic EL device.

However, in the present invention, in order to prevent reverse transfer phenomenon of excitons, while significantly increasing the number of excitons in the light-emitting layer, in selecting the second host, differences in physical properties such as a HOMO energy level difference or a LUMO energy level difference with respect to the first host needs to be considered.

According to an embodiment, the second host may be a material satisfying the following Relational Expressions 1 and 2:

|LUMOₕₒₛₜ₋₁|>|LUMOₕₒₛₜ₋₂| [Relational Expression 1]

|HOMOₕₒₛₜ₋₁|>|HOMOₕₒₛₜ₋₂| [Relational Expression 2]

in the above Relational Expressions,

LUMOₕₒₛₜ₋₁ is a LUMO energy level of the first host,

LUMOₕₒₛₜ₋₂ is a LUMO energy level of the second host,

HOMOₕₒₛₜ₋₁ is a HOMO energy level of the first host, and

HOMOₕₒₛₜ₋₂ is a HOMO energy level of the second host.

Specifically, a difference between an absolute value of the LUMO energy level of the second host and an absolute value of the LUMO energy level of the first host may be in a range of greater than 0 eV to 1.0 eV or less, and a difference between an absolute value of the HOMO energy level of the second host and an absolute value of the HOMO energy level of the first host may be in a range of greater than 0 eV to 1.0 eV or less.

A content of hosts (e.g., the first host) that are the same as the electron transport auxiliary layer material from among the plurality of hosts may be in a range of 30 to 90 percent by weight (wt %) with respect to the total amount of entire hosts. For example, when the plurality of hosts include the first host which is the same as the electron transport auxiliary layer material and the second host different from the first host, a use ratio of the first host and the second host is not particularly limited, and for example, the ratio may be in a range of 30:70 to 90:10 by weight. If the use ratio of the first host and the second host is within the above ratio, the dopant-to-host exciton reverse transfer phenomenon may be more effectively prevented, while achieving increased barrier-free effects between the light-emitting layer and the electron transport auxiliary layer.

Optionally, the light-emitting layer of the present invention may further include one or more other hosts (e.g., a third host) different from the first and second hosts described above. In such a case, an example of the third host may be the same as the examples of the second host, and thus description thereof will be omitted.

In the light-emitting layer of the present invention, any dopant commonly known in the art may be used as the dopant without particular limitation. Such dopants may be classified into fluorescent dopants and phosphorescent dopants, and the phosphorescent dopant may be an organometallic complex including Ir, Pt, Os, Re, Ti, Zr, Hf, or a combination of two or more thereof, but embodiments are not limited thereto.

In an embodiment, the dopant may be classified into red dopants, green dopants, and blue dopants, and red dopants, green dopants, and blue dopants commonly known in the art may be used without particular limitation.

Specifically, non-limiting examples of the red dopant may include PtOEP (Pt(II) octaethylporphine), Ir(piq)₃ (tris(2-phenylisoquinoline)iridium), Btp₂Ir(acac) (bis(2-(2′-benzothienyl)-pyridinato-N,C3′)iridium(acetylacetonate), and the like, which may be used solely or in combination of two or more thereof.

In addition, non-limiting examples of the green dopant may include Ir(ppy)₃ (tris(2-phenylpyridine) iridium), Ir(ppy)₂(acac) (bis(2-phenylpyridine)(Acetylacetonato)iridium(III)), Ir(mppy)₃ (tris(2-(4-tolyl)phenylpiridine)iridium), C545T (10-(2-benzothiazolyl)-1,1,7,7-tetramethyl-2,3,6,7-tetrahydro-1H,5H,11H-[1]benzopyrano [6,7,8-ij]-quinolizin-11-one, and the like, which may be used solely or in combination of two or more thereof.

In addition, non-limiting examples of the blue dopant may include F₂Irpic (bis[3,5-difluoro-2-(2-pyridyl)phenyl](picolinato)iridium(III)), (F₂ppy)₂Ir(tmd), Ir(dfppz)₃, DPVBi (4,4′-bis(2,2′-diphenylethen-1-yl)biphenyl), DPAVBi (4,4′-Bis[4-(diphenylamino)styryl]biphenyl), TBPe (2,5,8,11-tetra-tert-butyl perylene), and the like, which may be used solely or in combination of two or more thereof.

Contents of the dopants are not particularly limited and may be appropriately adjusted within a range known in the art.

For example, the plurality of hosts and the plurality of dopants may be included with a weight ratio in a range of 70:30 to 99.9:0.1 with respect to the total amount of the light-emitting layer. Specifically, when the light-emitting layer 320 is blue fluorescent, green fluorescent, or red fluorescent, the plurality of hosts and the plurality of dopants may be included with a weight ratio in a range of 80:20 to 99.9:0.1. In addition, when the light-emitting layer 320 is blue fluorescent, green fluorescent, or red phosphorescent, the plurality of hosts and the plurality of dopants may be included with a weight ratio in a range of 70:30 to 99:1.

In another example, the content of the dopant may be in a range of about 0 to 30 parts by weight, specifically more than 0 parts by weight to 20 pats by weight or less, more specifically in a range of about 0.1 to 15 parts by weight, with respect to 100 parts by weight of the total amount of the first hosts and the second hosts.

The above-described light-emitting layer 320 may be a single layer or may be formed of a plurality of layers of two or more layers. In such a case, when the light-emitting layer 320 includes a plurality of layers, the organic EL device may emit light of various colors. Specifically, the present invention may provide an organic EL device having a mixed color by providing, in series, a plurality of light-emitting layers including or formed of heterogeneous materials. In addition, when including the plurality of light-emitting layers, a driving voltage of the device may increase, while a current value in the organic EL device becomes constant, and accordingly, it is possible to provide an organic EL device with improved luminous efficiency by the number of light-emitting layers.

The light-emitting layer 320 may be formed through a conventional method known in the art. For example, there may be a vacuum deposition method, a spin coating method, a casting method, a Langmuir-Blodgett (LB) method, an inkjet printing method, a laser printing method, a laser induced thermal imaging (LITI) method, and the like, but embodiments are not limited thereto. For example, the light-emitting layer may be formed by co-deposition of the plurality of hosts (e.g., a first host and a second host) mixed with each other.

3) Electron Transport Region

In the organic EL device according to the present invention, the electron transport region 330 is an organic layer disposed on the light-emitting layer 320, and allows electrons injected from the cathode 200 to migrate to the light-emitting layer 320.

The electron transport region 330 includes the electron transport auxiliary layer 331, the electron transport layer 332, and the electron injection layer 333 sequentially disposed on the light-emitting layer 320.

The electron transport auxiliary layer 331 according to the present invention facilitates migration of electrons from the electron transport layer 332 to the light-emitting layer 320, and prevents excitons generated in the light-emitting layer 320 or holes injected into the light-emitting layer 320 from being diffused (e.g., migrating) to the electron transport layer 332. A material for forming the electron transport auxiliary layer 331 is also not particularly limited as long as it has a low electron injection barrier and high electron mobility, and any material known in the art may be used without particular limitation.

However, in the present invention, in order to achieve barrier-free effects between the light-emitting layer and the electron transport auxiliary layer, a material of the electron transport auxiliary layer may be the same as one of the plurality of hosts (e.g., the first host) in the light-emitting layer. In particular, the electron transport auxiliary layer may be formed by using a host having a low electron injection barrier and a high electron mobility from among the plurality of hosts in the light-emitting layer. Accordingly, in the organic EL device of the present invention, electrons injected from the electron transport layer may be smoothly supplied to the light-emitting layer through the electron transport auxiliary layer, such that a combination rate between holes and electrons may be increased, and thus the number of excitons may be significantly increased. Accordingly, the organic EL device of the present invention may exhibit high-efficiency luminous characteristics, and furthermore, as the driving voltage is lowered, life-span characteristics may be significantly improved.

In such a case, in order to achieve the barrier-free effects between the electron transport auxiliary layer 331 and the light-emitting layer 320 as well as to lower the electron injection barrier between the electron transport auxiliary layer 331 and the electron transport layer 332, a material of the electron transport auxiliary layer 331 needs to be selected in consideration of physical properties such as a difference in HOMO energy level or a difference in LUMO energy level between the electron transport auxiliary layer 331, the electron transport layer 332, and the light-emitting layer 320.

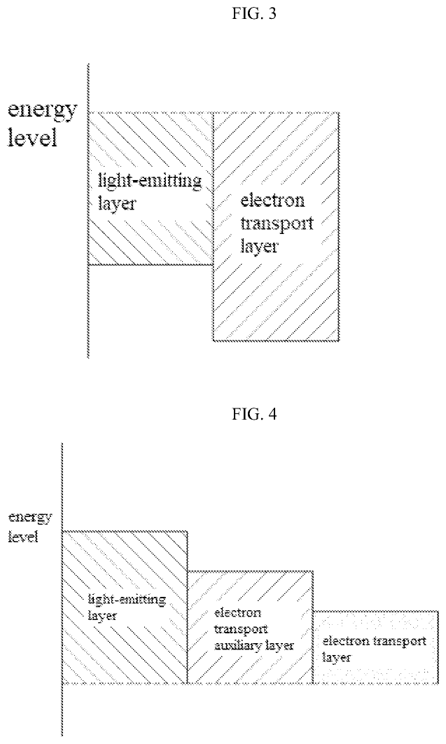

According to an embodiment, the material of the electron transport auxiliary layer may be selected so that the electron transport auxiliary layer 331 of the present invention satisfies the following Relational Expression 3 (see FIG. 3):

|HOMO_{aETL}|>|HOMO_{EL}| [Relational Expression 3]

(in the above formula,

HOMO_{aETL} is a HOMO energy level of the electron transport auxiliary layer, and

HOMO_{EL} is a HOMO energy level of the light-emitting layer).

Specifically, a difference between an absolute value of the HOMO energy level of the electron transport auxiliary layer 331 and an absolute value of the HOMO energy level of the light-emitting layer 320 may be in a range of greater than 0 eV to 1.0 eV or less.

As such, when the absolute value of the HOMO energy level of the electron transport auxiliary layer 331 is greater than the absolute value of the HOMO energy level of the light-emitting layer 320, holes in the light-emitting layer may be blocked by the energy barrier of the electron transport auxiliary layer and migration to the electron transport auxiliary layer may be prevented, and thus combination of electrons and holes in the light-emitting layer may be increased.

According to another embodiment, the material of the electron transport auxiliary layer may be selected so that the electron transport auxiliary layer 331 of the present invention satisfies the following Relational Expression 4 (see FIG. 4):

|LUMO_{ETL}|>|LUMO_{aETL}|>|HOMO_{EL}| [Relational Expression 4]

(in the above formula,

LUMO_{ETL} is a LUMO energy level of the electron transport layer,

LUMO_{aETL} is a LUMO energy level of the electron transport auxiliary layer, and

LUMO_{EL} is a LUMO energy level of the light-emitting layer).

Specifically, a difference between an absolute value of the LUMO energy level of the electron transport auxiliary layer 331 and an absolute value of the LUMO energy level of the electron transport layer 332 may be in a range of greater than 0 eV to 1.0 eV or less. In addition, a difference between an absolute value of the LUMO energy level of the electron transport auxiliary layer 331 and an absolute value of the LUMO energy level of the light-emitting layer 320 may be in a range of greater than 0 eV to 1.0 eV or less.

As such, when the absolute value of the LUMO energy level of the electron transport auxiliary layer 331 is between the absolute value of the LUMO energy level of the electron transport layer 332 and the absolute value of the LUMO energy level of the light-emitting layer 320, the LUMO energy level may have a step arrangement, and electrons injected from the cathode may be smoothly injected from the electron transport layer to the light-emitting layer.

Any material having physical properties such as the above-described HOMO energy level and LUMO energy level may be used as the electron transport auxiliary layer material of the present invention.

For example, the material of the electron transport auxiliary layer 331 of the present invention may be a compound including one or more of moieties represented by the following Chemical Formulas 1 and 2 (“one or more moiety-containing compounds”):

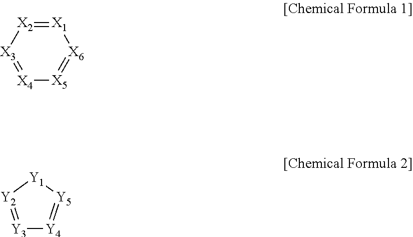

where in Chemical Formulas 1 and 2,

X₁ to X₆ may be the same as or different from each other, each independently being N or C(R₁), where at least one of X₁ to X₆ (specifically, one to three of X₁ to X₆) may be N, and when C(R₁) is plural in number, the plurality of R₁ may be the same as or different from each other,

Y₁ to Y₅ may be the same as or different from each other, each independently being N or C(R₂), where at least one of Y₁ to Y₅ (specifically, one to three of Y₁ to Y₅) may be N, and when C(R₂) is plural in number, the plurality of R₂ may be the same as or different from each other,

R₁ and R₂ may be the same as or different from each other, each independently being selected from: hydrogen, deuterium, a halogen group, a cyano group, a nitro group, an amino group, a C₁ to C₄₀ alkyl group, a C₂ to C₄₀ alkenyl group, a C₂ to C₄₀ alkynyl group, a C₃ to C₄₀ cycloalkyl group, a heterocycloalkyl group having 3 to 40 nuclear atoms, a C₆ to C₆₀ aryl group, a heteroaryl group having 5 to 60 nuclear atoms, a C₁ to C₄₀ alkyloxy group, a C₆ to C₆₀ aryloxy group, a C₁ to C₄₀ alkylsilyl group, a C₆ to C₆₀ arylsilyl group, a C₁ to C₄₀ alkylboron group, a C₆ to C₆₀ arylboron group, a C₆ to C₆₀ arylphosphine group, a C₆ to C₆₀ arylphosphine oxide group and a C₆ to C₆₀ arylamine group, or forming a fused ring (e.g., a condensed ring) with an adjacent group, and

the alkyl group, the alkenyl group, the alkynyl group, the aryl group, the heteroaryl group, the aryloxy group, the alkyloxy group, the cycloalkyl group, the heterocycloalkyl group, the arylamine group, the alkylsilyl group, the alkylboron group, the arylboron group, the phosphine group, and the phosphine oxide group of R₁ and R₂ may each be independently substituted or unsubstituted with one or more substituents of: hydrogen, deuterium (D), a halogen group, a cyano group, a nitro group, a C₁ to C₄₀ alkyl group, a C₂ to C₄₀ alkenyl group, a C₂ to C₄₀ alkynyl group, a C₃ to C₄₀ cycloalkyl group, a heterocycloalkyl group having 3 to 40 nuclear atoms, a C₆ to C₆₀ aryl group, a heteroaryl group having 5 to 60 nuclear atoms, a C₁ to C₄₀ alkyloxy group, a C₆ to C₆₀ aryloxy group, a C₁ to C₄₀ alkylsilyl group, a C₆ to C₆₀ arylsilyl group, a C₁ to C₄₀ alkylboron group, a C₆ to C₆₀ arylboron group, a C₆ to C₆₀ arylphosphine group, a C₆ to C₆₀ arylphosphine oxide group and a C₆ to C₆₀ arylamine group, and when the substituents are plural in number, the substituents may be the same as or different from each other.

In Chemical Formula 1, when R₁ combines with an adjacent group to form a fused ring, the moiety represented by Chemical Formula 1 may be a moiety represented by Chemical Formula 3, but embodiments are not limited thereto:

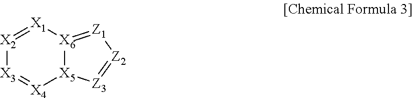

where in Chemical Formula 3,

X₁ to X₆ may be the same as those defined in Chemical Formula 1 above, respectively,

Z₁ to Z₃ may be the same as or different from each other, each independently being N or C(R₃), where at least one of Z₁ to Z₃ (specifically, one or two of Z₁ to Z₃) is N, and when C(R₃) is plural in number, the plurality of R₃ are the same as or different from each other,

R₃ may be selected from: hydrogen, deuterium, a halogen group, a cyano group, a nitro group, an amino group, a C₁ to C₄₀ alkyl group, a C₂ to C₄₀ alkenyl group, a C₂ to C₄₀ alkynyl group, a C₃ to C₄₀ cycloalkyl group, a heterocycloalkyl group having 3 to 40 nuclear atoms, a C₆ to C₆₀ aryl group, a heteroaryl group having 5 to 60 nuclear atoms, a C₁ to C₄₀ alkyloxy group, a C₆ to C₆₀ aryloxy group, a C₁ to C₄₀ alkylsilyl group, a C₆ to C₆₀ arylsilyl group, a C₁ to C₄₀ alkylboron group, a C₆ to C₆₀ arylboron group, a C₆ to C₆₀ arylphosphine group, a C₆ to C₆₀ arylphosphine oxide group and a C₆ to C₆₀ arylamine group, or may form a fused ring with an adjacent group, and

the alkyl group, the alkenyl group, the alkynyl group, the aryl group, the heteroaryl group, the aryloxy group, the alkyloxy group, the cycloalkyl group, the heterocycloalkyl group, the arylamine group, the alkylsilyl group, the alkylboron group, the arylboron group, the phosphine group, and the phosphine oxide group of R₃ may be substituted or unsubstituted with one or more substituents of: hydrogen, deuterium, a halogen group, a cyano group, a nitro group, a C₁ to C₄₀ alkyl group, a C₂ to C₄₀ alkenyl group, a C₂ to C₄₀ alkynyl group, a C₃ to C₄₀ cycloalkyl group, a heterocycloalkyl group having 3 to 40 nuclear atoms, a C₆ to C₆₀ aryl group, a heteroaryl group having 5 to 60 nuclear atoms, a C₁ to C₄₀ alkyloxy group, a C₆ to C₆₀ aryloxy group, a C₁ to C₄₀ alkylsilyl group, a C₆ to C₆₀ arylsilyl group, a C₁ to C₄₀ alkylboron group, a C₆ to C₆₀ arylboron group, a C₆ to C₆₀ arylphosphine group, a C₆ to C₆₀ arylphosphine oxide group and a C₆ to C₆₀ arylamine group, and when the substituents are plural in number, the substituents may be the same as or different from each other.

The at least one moiety-containing compound described above has an electron withdrawing group (“EWG”) property in which the moieties of Chemical Formulas 1 and 2 have high electron absorbable properties. Accordingly, when the at least one moiety-containing compound is applied as materials of both of the electron transport auxiliary layer and one of the plurality of hosts of the light-emitting layer, electrons injected from the cathode may be smoothly supplied from the electron transport layer to the light-emitting layer, and accordingly, the driving voltage of the organic EL device may be lowered, and high efficiency and long lifespan may be induced.

In addition, the at least one moiety-containing compound has a high glass transition temperature because a molecular weight of the compound may be significantly increased by controlling various types and introduction positions of the substituents that are introduced into the moieties of Chemical Formulas 1 and 2, and thus thermal stability of the organic EL device may be improved, and there may also be an effect of inhibiting crystallization of the organic layer, and thus durability and lifespan characteristics of the device may be greatly improved.

Specifically, the at least one moiety-containing compound may be a compound represented by any one of the following Chemical Formulas 4 to 6, but embodiments are not limited thereto:

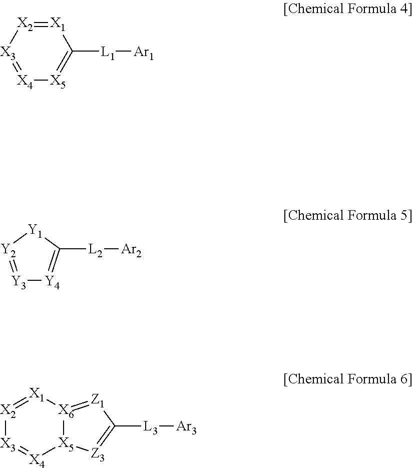

where in Chemical Formulas 4 to 6,

X₁ to X₅, Y₁ to Y₄, and Z₁ and Z₃ may be the same as those defined in Chemical Formulas 1 to 3, respectively,

L₁ to L₃ may be the same or different from each other, each independently being a single bond, or being selected from a C₆ to C₁₈ arylene group and a heteroarylene group having 5 to 18 nuclear atoms, specifically selected from: a single bond, a phenylene group, a biphenylene group, a terphenylene group, a divalent naphthyl group, a divalent phenanthryl group, a divalent anthracene group, a divalent pyrene group, a divalent chrysene group, a divalent carbazole group, a divalent dibenzofuran group, a divalent dibenzothiophene group, a divalent fluorene group, a divalent fluorancene group, a divalent triphenylene group, a divalent furan group, a divalent indole group, a divalent indene group, a divalent thiophene group, a divalent benzofuran group, a divalent benzothiophene group, a divalent benzoindene group, and combinations of two or more thereof, and

Ar₁ to Ar₃ may be the same as or different from each other, each independently being a substituent selected from the following Chemical Formulas S1 to S9:

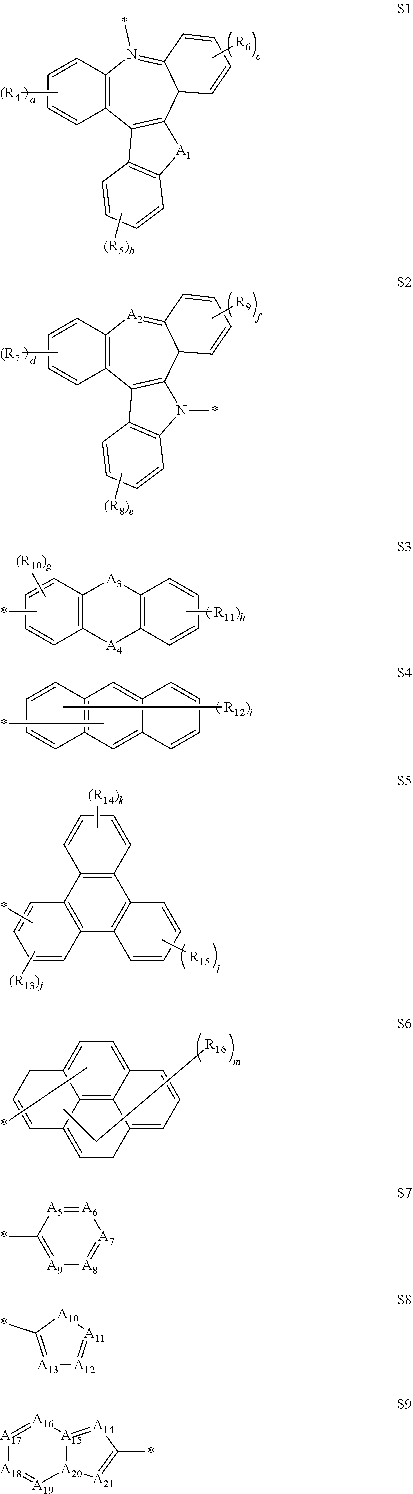

in Chemical Formulas S1 to S9,

A₁ and A₂ may be N or CR₁₇,

A₃ and A₄ may be the same as or different from each other, each independently being a single bond, or being selected from: NR₁₈, O, S, and CR₁₉R₂₀, wherein a case where both of A₃ and A₄ are single bonds is excluded,

A₅ to A₉ may be N or CR₂₁, where at least one of A₅ to A₉ (specifically, one to three of A₅ to A₉) is N, and when CR₂₁ is plural in number, the plurality of R₂₁ are the same as or different from each other,

A₁₀ to A₁₃ may be N or CR₂₂, where at least one of A₁₀ to A₁₃ (specifically, one to three of A₁₀ to A₁₃) is N, and when CR₂₂ is plural in number, the plurality of R₂₂ are the same as or different from each other,

A₁₄ to A₂₁ may be N or CR₂₃, where at least one of A₁₄ to A₂₁ (specifically, one to four of A₁₄ to A₂₁) is N, and when CR₂₃ is plural in number, the plurality of R₂₃ are the same as or different from each other,

a, b, c, d, e, f, h, k, and 1 may each be an integer in a range of 0 to 4;

g and j may each be an integer in a range of 0 to 3,

i and m may each be an integer in a range of 0 to 9,

R₄ to R₂₃ may be the same as or different from each other, each independently being selected from: hydrogen, deuterium, a halogen group, a cyano group, a nitro group, an amino group, a C₁ to C₄₀ alkyl group, a C₂ to C₄₀ alkenyl group, a C₂ to C₄₀ alkynyl group, a C₃ to C₄₀ cycloalkyl group, a heterocycloalkyl group having 3 to 40 nuclear atoms, a C₆ to C₆₀ aryl group, a heteroaryl group having 5 to 60 nuclear atoms, a C₁ to C₄₀ alkyloxy group, a C₆ to C₆₀ aryloxy group, a C₁ to C₄₀ alkylsilyl group, a C₆ to C₆₀ arylsilyl group, a C₁ to C₄₀ alkylboron group, a C₆ to C₆₀ arylboron group, a C₆ to C₆₀ arylphosphine group, a C₆ to C₆₀ arylphosphine oxide group and a C₆ to C₆₀ arylamine group, or forming a fused ring with an adjacent group, and

the alkyl group, the alkenyl group, the alkynyl group, the aryl group, the heteroaryl group, the aryloxy group, the alkyloxy group, the cycloalkyl group, the heterocycloalkyl group, the arylamine group, the alkylsilyl group, the alkylboron group, the arylboron group, the phosphine group, and the phosphine oxide group of R₄ to R₂₃ may each independently be substituted or unsubstituted with one or more substituents of: hydrogen, deuterium, a halogen group, a cyano group, a nitro group, a C₁ to C₄₀ alkyl group, a C₂ to C₄₀ alkenyl group, a C₂ to C₄₀ alkynyl group, a C₃ to C₄₀ cycloalkyl group, a heterocycloalkyl group having 3 to 40 nuclear atoms, a C₆ to C₆₀ aryl group, a heteroaryl group having 5 to 60 nuclear atoms, a C₁ to C₄₀ alkyloxy group, a C₆ to C₆₀ aryloxy group, a C₁ to C₄₀ alkylsilyl group, a C₆ to C₆₀ arylsilyl group, a C₁ to C₄₀ alkylboron group, a C₆ to C₆₀ arylboron group, a C₆ to C₆₀ arylphosphine group, a C₆ to C₆₀ arylphosphine oxide group and a C₆ to C₆₀ arylamine group, and when the substituents are plural in number, the substituents may be the same as or different from each other.

Specifically, the compound represented by any one of the above Chemical Formulas 4 to 6 may be one of compounds represented by the following Chemical Formulas A-1 to A-16, but embodiments are not limited thereto:

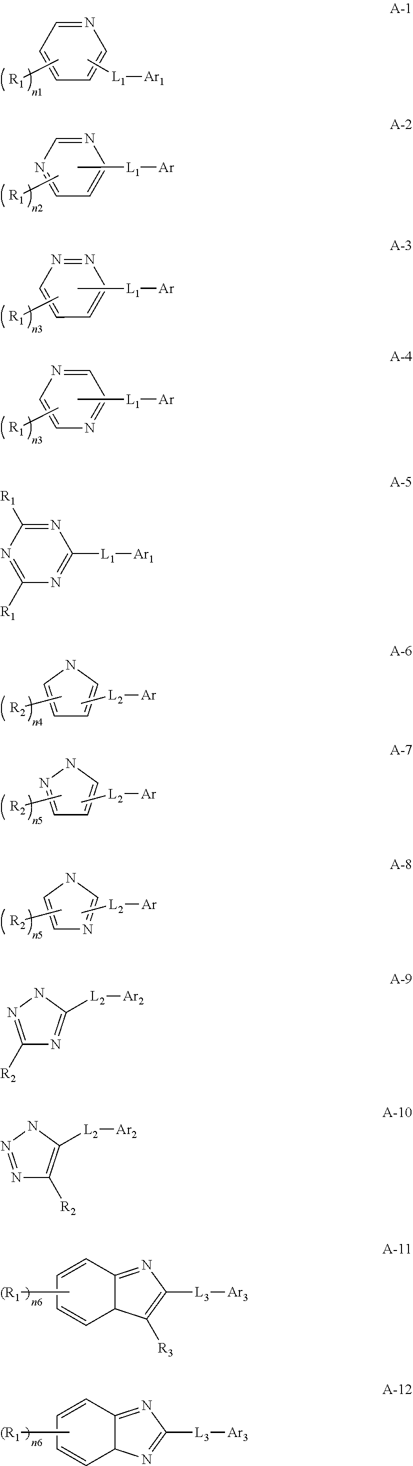

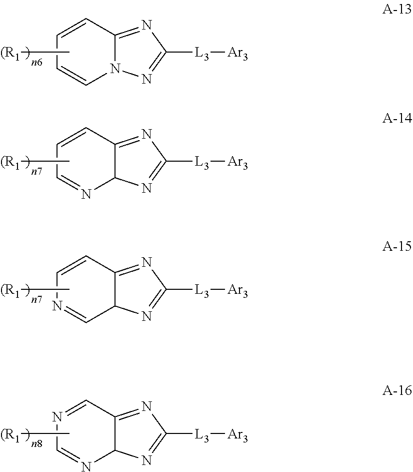

where in Chemical Formulas A-1 to A-16,

R₁ and R₂ may be the same as those defined in Chemical Formulas 1 to 3, respectively,

L₁ to L₃ and Ar₁ to Ar₃ may be the same as those defined in Chemical Formulas 4 to 6, respectively,

n₁ and n₆ may each be an integer in a range of 0 to 4,

n₂, n₃, n₄, and n₇ may each be an integer in a range of 0 to 3, and

n₅ and n₈ may each be an integer in a range of 0 tot.

More specifically, the compound represented by any one of Chemical Formulas 4 to 6 may selected from compounds represented by the following Chemical Formulas B-1 to B-9, but embodiments are not limited thereto:

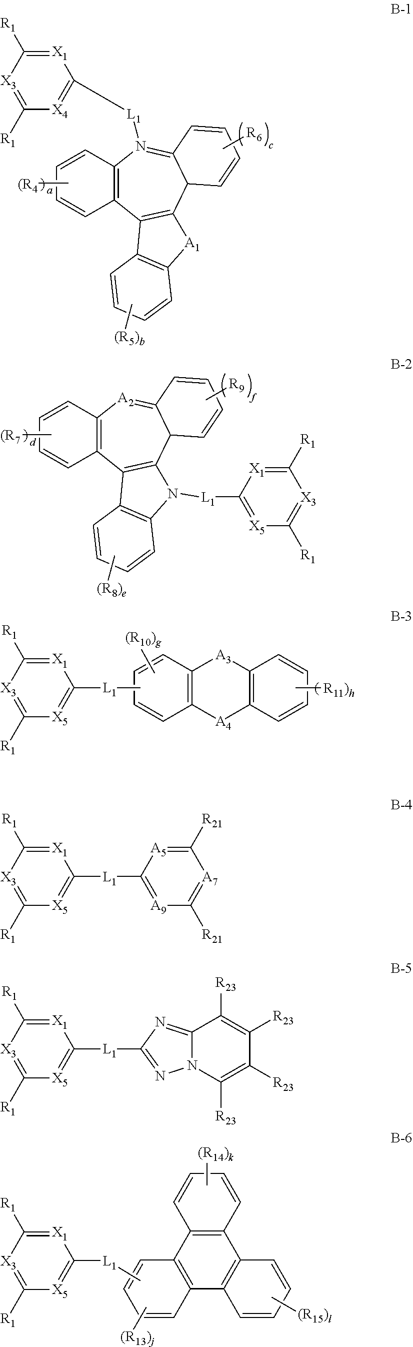

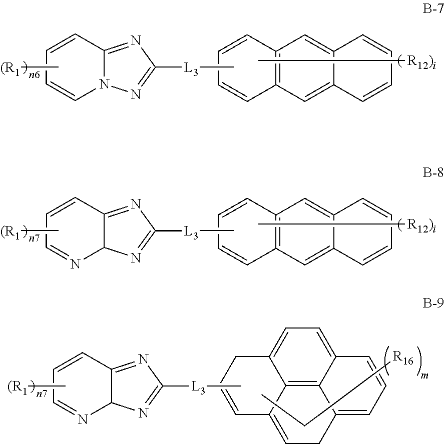

where in the above Chemical Formulas B-1 to B-9,

X₁, X₃, X₅, and R₁ may be the same as those defined in Chemical Formulas 1 to 3, respectively,

L₁ and L₃ may be the same as those defined in Chemical Formulas 4 to 6, respectively,

A₁ to A₅, A₇, A₉, R₄ to R₁₆, R₂₁, R₂₃, a to h may be the same as those defined in Chemical Formulas S1 to S9, respectively, and

n₆ and n₇ may be the same as those defined in Chemical Formulas A-1 to A-16, respectively.

The compound containing one or more moieties described above may be embodied as, but not limited to, compounds 1 to 14 below.

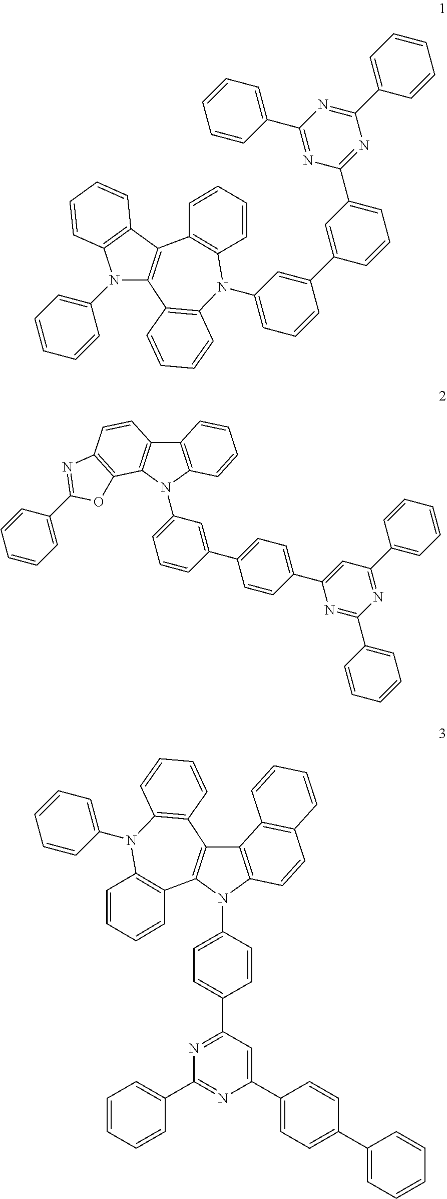 [SMILES: c1ccc(-c2nc(-c3ccccc3)nc(-c3cccc(-c4cccc(N5c6ccccc6-c6c(n(-c7ccccc7)c7ccccc67)-c6ccccc65)c4)c3)n2)cc1 ; c1ccc(-c2cc(-c3ccc(-c4cccc(-n5c6ccccc6c6ccc7nc(-c8ccccc8)oc7c65)c4)cc3)nc(-c3ccccc3)n2)cc1 ; c1ccc(-c2ccc(-c3cc(-c4ccc(-n5c6c(c7c8ccccc8ccc75)-c5ccccc5N(c5ccccc5)c5ccccc5-6)cc4)nc(-c4ccccc4)n3)cc2)cc1]

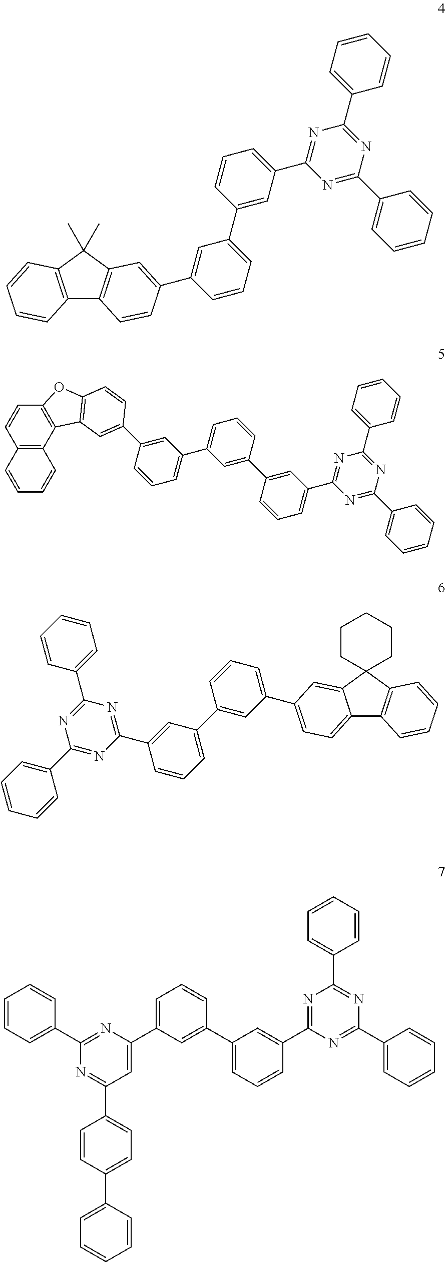 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-c4cccc(-c5cccc(-c6ccc7oc8ccc9ccccc9c8c7c6)c5)c4)c3)n2)cc1 ; c1ccc(-c2nc(-c3ccccc3)nc(-c3cccc(-c4cccc(-c5ccc6c(c5)C5(CCCCC5)c5ccccc5-6)c4)c3)n2)cc1 ; c1ccc(-c2ccc(-c3cc(-c4cccc(-c5cccc(-c6nc(-c7ccccc7)nc(-c7ccccc7)n6)c5)c4)nc(-c4ccccc4)n3)cc2)cc1]

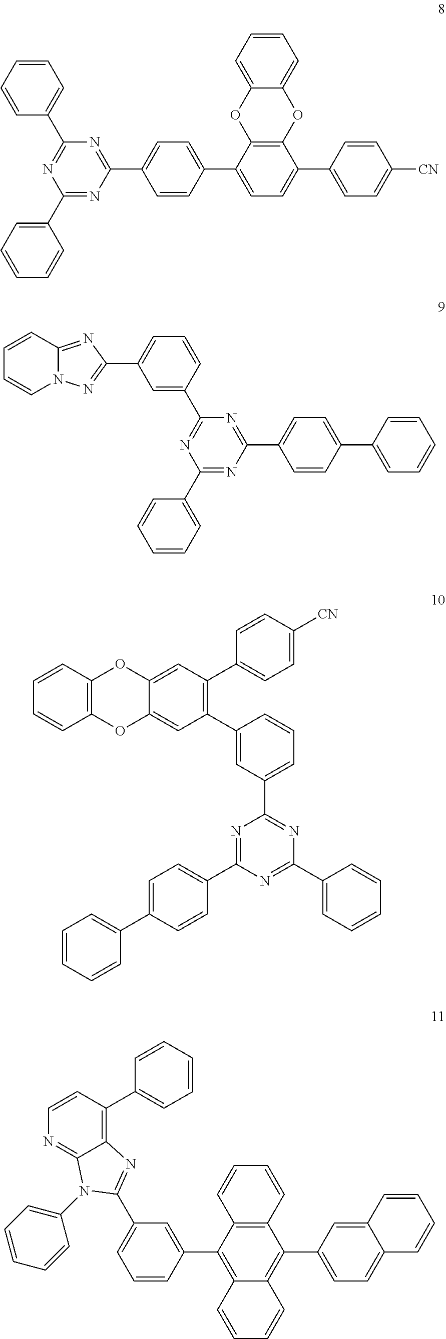 [SMILES: N#Cc1ccc(-c2ccc(-c3ccc(-c4nc(-c5ccccc5)nc(-c5ccccc5)n4)cc3)c3c2Oc2ccccc2O3)cc1 ; c1ccc(-c2ccc(-c3nc(-c4ccccc4)nc(-c4cccc(-c5nc6ccccn6n5)c4)n3)cc2)cc1 ; N#Cc1ccc(-c2cc3c(cc2-c2cccc(-c4nc(-c5ccccc5)nc(-c5ccc(-c6ccccc6)cc5)n4)c2)Oc2ccccc2O3)cc1 ; c1ccc(-c2ccnc3c2nc(-c2cccc(-c4c5ccccc5c(-c5ccc6ccccc6c5)c5ccccc45)c2)n3-c2ccccc2)cc1]

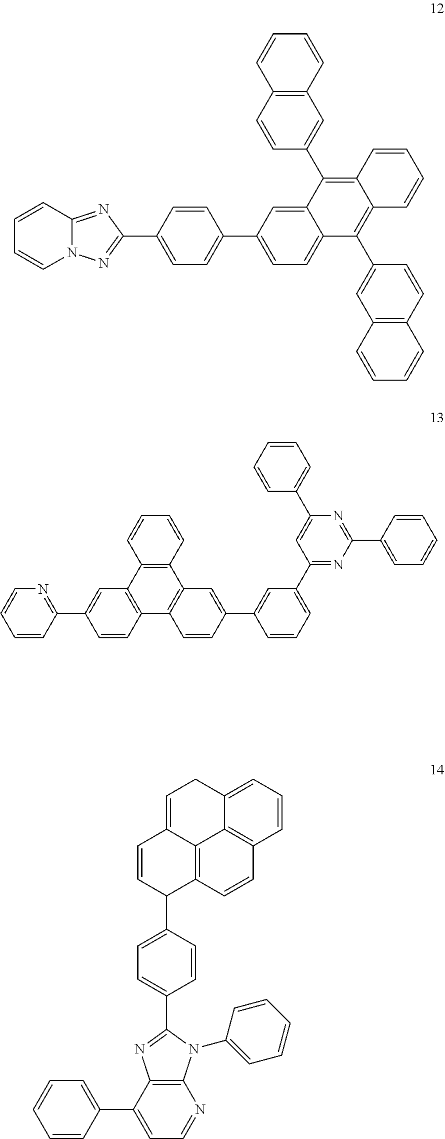 [SMILES: c1ccc2cc(-c3c4ccccc4c(-c4ccc5ccccc5c4)c4cc(-c5ccc(-c6nc7ccccn7n6)cc5)ccc34)ccc2c1 ; c1ccc(-c2cc(-c3cccc(-c4ccc5c6ccc(-c7ccccn7)cc6c6ccccc6c5c4)c3)nc(-c3ccccc3)n2)cc1 ; C1=CC(c2ccc(-c3nc4c(-c5ccccc5)ccnc4n3-c3ccccc3)cc2)c2ccc3cccc4c3c2C1=CC4]

In the electron transport region 330 according to the present invention, any electron transport material that facilitates electron injection and has high electron mobility may be used as the electron transport layer 332 without limitation. Non-limiting examples of the electron transport material may include an oxazole-based compound, an isoxazole-based compound, a triazole-based compound, an isothiazole-based compound, an oxadiazole-based compound, a thiadiazole-based compound, a perylene-based compound, an aluminum complex [e.g., Alq₃ (tris(8-quinolinolato)-aluminium), BAlq, SAlq, Alph₃, Almq₃], a gallium complex (e.g., Gaq'2OPiv, Gaq'2OAc, 2(Gaq'2)) and the like, which may be used solely or in combination of two or more thereof.

In addition, as the electron injection layer 333, any electron injection material that facilitates electron injection and has high electron mobility may be used without limitation. Non-limiting examples of the electron injection material may include LiF, Li₂O, BaO, NaCl, and CsF; lanthanide metals such as Yb; a metal halide such as RbCl or RbI, and the like, which may be used solely or in combination of two or more thereof.

The electron transport region 330 according to the present invention, specifically, the electron transport layer 332 and/or the electron injection layer 333 may be co-deposited with an n-type dopant to facilitate injection of electrons from the cathode. In such a case, as the n-type dopant, alkali metal complex compounds known in the art may be used without limitation, and examples thereof may include alkali metals, alkaline earth metals, or rare earth metals.

The electron transport region 330 may be formed through a conventional method known in the art. For example, there may be a vacuum deposition method, a spin coating method, a casting method, a Langmuir-Blodgett (LB) method, an inkjet printing method, a laser printing method, a laser induced thermal imaging (LITI) method, and the like, but embodiments are not limited thereto.

4) Light-Emitting Auxiliary Layer

Optionally, the organic EL device 100 of the present invention may further include a light-emitting auxiliary layer (not illustrated) disposed between the hole transport region 310 and the light-emitting layer 320.

The light-emitting auxiliary layer serves to control a thickness of the organic layer 300, while transporting holes migrating from the hole transport region 310 to the light-emitting layer 320, or blocking migration of electrons and/or excitons. In particular, the light-emitting auxiliary layer has a high LUMO value to prevent electrons from migrating to the hole transport layer 312 (or the hole transport auxiliary layer 313), and has a high triplet energy to prevent excitons of the light-emitting layer 320 from being diffused to the hole transport layer 312 (or the hole transport auxiliary layer 313).

The light-emitting auxiliary layer may include a hole transport material and may include or be formed of a material the same as a material of the hole transport region. In addition, the light-emitting auxiliary layers of the red, green, and blue organic EL devices may include or be formed of the same material.

A material for the light-emitting auxiliary layer is not particularly limited, and examples thereof may include carbazole derivatives and arylamine derivatives. Specifically, examples of the light-emitting auxiliary layer may include NPD (N,N-dinaphthyl-N,N′-diphenyl benzidine), TPD (N,N′-bis-(3-methylphenyl)-N,N′-bis(phenyl)-benzidine), s-TAD, MTDATA (4,4′,4″-Tris(N-3-methylphenyl-Nphenyl-amino)-triphenylamine), and the like, but embodiments are not limited thereto. These may be used solely or two or more of them may be used in combination with each other.

The light-emitting auxiliary layer may further include a p-type dopant in addition to the above-described material. As the applicable p-type dopant according to the present invention, any known p-type dopant generally used in the art may be used without particular limitation. In such a case, a content of the p-type dopant may be appropriately adjusted within a range known in the art, for example, in a range of about 0.5 to 50 parts by weight with respect to 100 parts by weight of the hole transport material.

The light-emitting auxiliary layer may be formed by a vacuum deposition method, a spin coating method, a casting method, a Langmuir-Blodgett (LB) method, an inkjet printing method, a laser printing method, a laser induced thermal imaging (LITI) method, and the like known in the art, but embodiments are not limited thereto.

(4) Capping Layer

Optionally, the organic EL device 100 of the present invention may further include a capping layer (not illustrated) disposed on the above-described cathode 200.

The capping layer may serve to allow light generated in the organic layer to be efficiently emitted to the outside while protecting the organic EL device.

The capping layer may include at least one of tris-8-hydroxyquinoline aluminum (Alq₃), ZnSe, 2,5-bis(6′-(2′,2″-bipyridyl))-1,1-dimethyl-3,4-diphenylsilole, 4′-bis[N-(1-napthyl)-N-phenyl-amion] biphenyl (α-NPD), N,N′-diphenyl-N,N′-bis(3-methylphenyl)-1,1′-biphenyl-4,4′-diamine (TPD), and 1,1′-bis(di-4-tolylaminophenyl) cyclohexane (TAPC). The material for forming such a capping layer is inexpensive as compared to materials of other layers of the organic EL device.

The capping layer may be a single layer, but may include two or more layers having different refractive indices so that the refractive index gradually changes while passing through the two or more layers.

The capping layer may be prepared by a conventional method known in the art, and for example, various methods such as a vacuum deposition method, a spin coating method, a casting method, or a Langmuir-Blodgett (LB) method may be used.

As such, the organic EL device according to the present invention has a structure in which the anode 100, the organic layer 300 and the cathode 200 are sequentially stacked. In some cases, an insulating layer (not illustrated) or an adhesive layer (not illustrated) may be further included between the anode 100 and the organic layer 300 or between the cathode 200 and the organic layer 300. The organic EL device of the present invention may have excellent lifespan characteristics because a half-life time of initial brightness is increased while maintaining maximum luminous efficiency when voltage and current are applied.

The organic EL device of the present invention described above may be prepared according to a conventional method known in the art. For example, after vacuum deposition of an anode material on a substrate, a hole transport region material, a light-emitting layer material, an electron transport region material, and a cathode material may be vacuum-deposited on the anode, and thus an organic EL device may be manufactured.

Hereinafter, the present invention will be described in detail through embodiments, but the following embodiments are merely illustrative of the present invention, and the present invention is not limited by the following embodiments.

### [Preparation Examples 1 to 14] Measurement of HOMO, LUMO and Triplet Energy of Compounds 1 to 20

The following Compounds 1 to 14 were prepared as materials of the first host and the electron transport auxiliary layer of the present invention, and their HOMO and LUMO were measured by methods known in the art, respectively, which are shown in Table 1 below. In such a case, ADN and Alq₃ were used as controls. In Table 1, the HOMO energy level and the LUMO energy level are each described as absolute values.

1) HOMO Energy Level

A HOMO energy level of each compound was measured by cyclic voltammetry (CV) method.

2) LUMO Energy Level

After obtaining a bandgap energy of each compound as a UV spectrum, a LUMO energy level was obtained from a difference between the bandgap energy and the HOMO energy level.

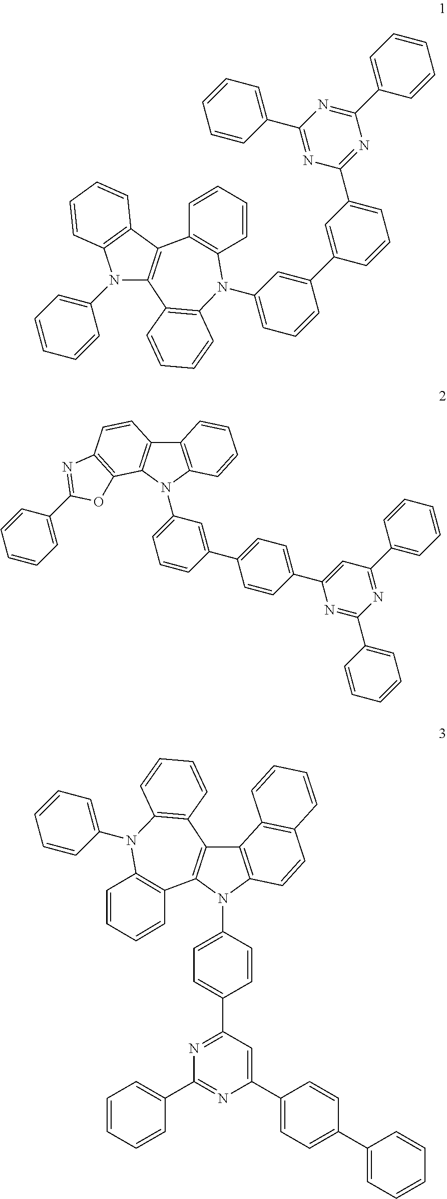 [SMILES: c1ccc(-c2nc(-c3ccccc3)nc(-c3cccc(-c4cccc(N5c6ccccc6-c6c(n(-c7ccccc7)c7ccccc67)-c6ccccc65)c4)c3)n2)cc1 ; c1ccc(-c2cc(-c3ccc(-c4cccc(-n5c6ccccc6c6ccc7nc(-c8ccccc8)oc7c65)c4)cc3)nc(-c3ccccc3)n2)cc1 ; c1ccc(-c2ccc(-c3cc(-c4ccc(-n5c6c(c7c8ccccc8ccc75)-c5ccccc5N(c5ccccc5)c5ccccc5-6)cc4)nc(-c4ccccc4)n3)cc2)cc1]

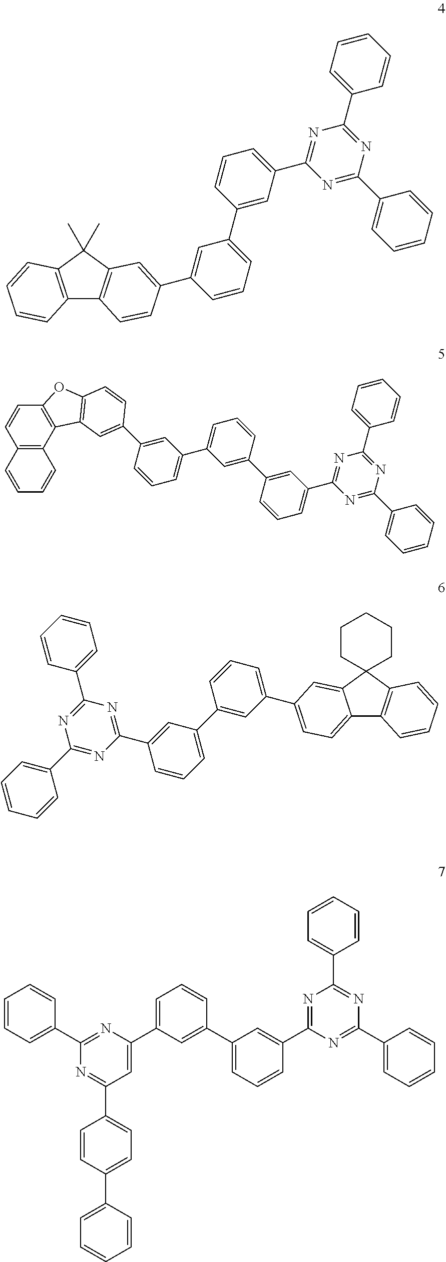 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-c4cccc(-c5cccc(-c6ccc7oc8ccc9ccccc9c8c7c6)c5)c4)c3)n2)cc1 ; c1ccc(-c2nc(-c3ccccc3)nc(-c3cccc(-c4cccc(-c5ccc6c(c5)C5(CCCCC5)c5ccccc5-6)c4)c3)n2)cc1 ; c1ccc(-c2ccc(-c3cc(-c4cccc(-c5cccc(-c6nc(-c7ccccc7)nc(-c7ccccc7)n6)c5)c4)nc(-c4ccccc4)n3)cc2)cc1]

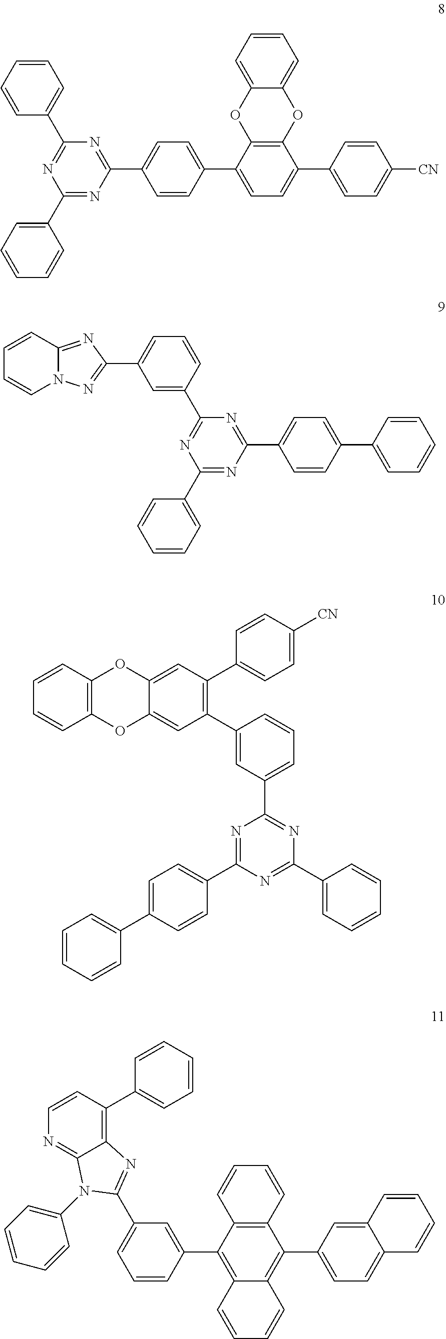 [SMILES: N#Cc1ccc(-c2ccc(-c3ccc(-c4nc(-c5ccccc5)nc(-c5ccccc5)n4)cc3)c3c2Oc2ccccc2O3)cc1 ; c1ccc(-c2ccc(-c3nc(-c4ccccc4)nc(-c4cccc(-c5nc6ccccn6n5)c4)n3)cc2)cc1 ; N#Cc1ccc(-c2cc3c(cc2-c2cccc(-c4nc(-c5ccccc5)nc(-c5ccc(-c6ccccc6)cc5)n4)c2)Oc2ccccc2O3)cc1 ; c1ccc(-c2ccnc3c2nc(-c2cccc(-c4c5ccccc5c(-c5ccc6ccccc6c5)c5ccccc45)c2)n3-c2ccccc2)cc1]

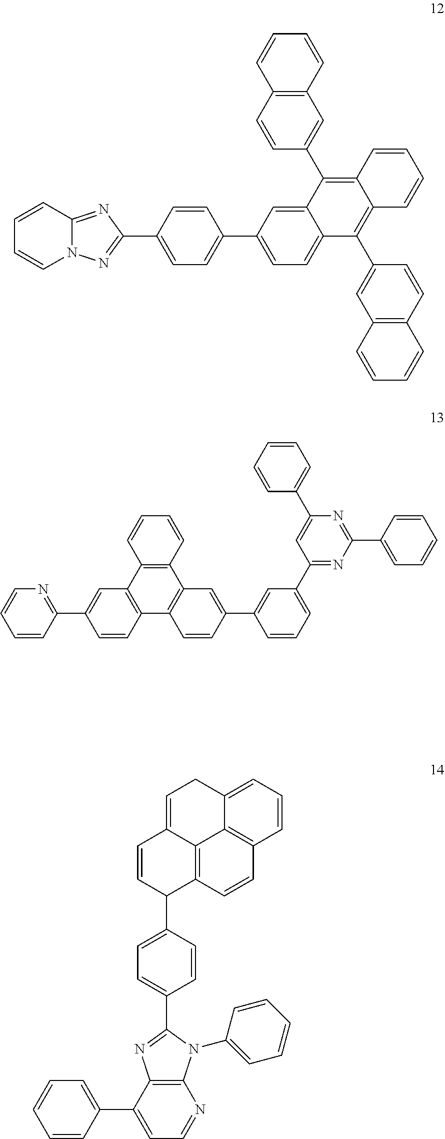 [SMILES: c1ccc2cc(-c3c4ccccc4c(-c4ccc5ccccc5c4)c4cc(-c5ccc(-c6nc7ccccn7n6)cc5)ccc34)ccc2c1 ; c1ccc(-c2cc(-c3cccc(-c4ccc5c6ccc(-c7ccccn7)cc6c6ccccc6c5c4)c3)nc(-c3ccccc3)n2)cc1 ; C1=CC(c2ccc(-c3nc4c(-c5ccccc5)ccnc4n3-c3ccccc3)cc2)c2ccc3cccc4c3c2C1=CC4]

TABLE 1

| Compound | HOMO (eV) | LUMO (eV) |
|---|---|---|
| 1 | 5.97 | 2.67 |
| 2 | 5.82 | 2.67 |
| 3 | 5.84 | 2.71 |
| 4 | 5.83 | 2.64 |
| 5 | 6.02 | 2.64 |
| 6 | 5.82 | 2.67 |
| 7 | 6.25 | 2.75 |
| 8 | 5.85 | 2.76 |
| 9 | 6.22 | 2.65 |
| 10 | 5.83 | 2.71 |
| 11 | 5.81 | 2.75 |
| 12 | 5.82 | 2.79 |
| 13 | 5.98 | 2.77 |
| 14 | 6.05 | 2.67 |
| ADN | 5.80 | 2.62 |
| Alq₃ | 5.62 | 2.80 |

### [Embodiment 1]—Manufacturing of Blue Organic EL Device

After high-purity sublimation purification of Compound 1 prepared in Preparation Example 1 by a commonly known method, a blue organic EL device was prepared according to the following procedure.

First, a glass substrate that had been thin-film-coated with indium tin oxide (ITO) to a thickness of 1500 Å was washed ultrasonically with distilled water. After washing with distilled water was completed, the glass substrate was ultrasonically cleaned with a solvent, such as isopropyl alcohol, acetone and methanol, dried, transferred to a UV OZONE cleaner (Power sonic 405, Hwasin Tech), and cleaned for 5 minutes using UV, and then, the glass substrate was transferred to a vacuum evaporator.

On the ITO transparent electrode prepared as above, DS-205 (Doosan Corporation Electro-Materials) (80 nm)/NPB (15 nm)/Compound 1+ADN+5% DS-405 (Doosan Corporation Electro-Materials) (30 nm)/Compound 1 (5 nm)/Alq₃ (25 nm)/LiF (1 nm)/Al (200 nm) were stacked in the order, and thus an organic EL device was manufactured. In such a case, the structures of NPB, ADN, and Alq₃ used are as follows. In such a case, in the light-emitting layer, Compound 1 was used as the first host (‘A’ in the table 1), and ADN was used as the second host (‘B’ in the table 1).

### [Embodiments 2-14]—Manufacturing of Blue Organic EL Device

Blue organic EL devices of Embodiments 2 to 14 were manufactured in the same manner as in Embodiment 1, except that each compound (‘A’) shown in Table 2 was used instead of Compound 1 which is the first host used in the formation of the light-emitting layer of Embodiment 1, and that each compound (‘C’) shown in Table 2 was used instead of Compound 1 used in the formation of the electron transport auxiliary layer.

### [Comparative Example 1]—Manufacturing of Blue Organic EL Device

A blue organic EL device was prepared in the same manner as in Embodiment 1, except that Compound 1 which is the first host was not used, and that only ADN which was the second host was used in the formation of the light-emitting layer of Embodiment 1.

### [Comparative Example 2]—Manufacturing of Blue Organic EL Device

A blue organic EL device was manufactured in the same manner as in Embodiment 1, except that only Compound 1 which is the first host was used and ADN which is the second host was not used in the formation of the light-emitting layer of Embodiment 1, the electron transport auxiliary layer was not formed, and the electron transport layer material Alq₃ was deposited to 30 nm instead of 25 nm.

### [Comparative Example 3]—Manufacturing of Blue Organic EL Device

A blue organic EL device was manufactured in the same manner as in Embodiment 1, except that Compound 1 which is the first host was not used and only AND which is the second host was used in the formation of the light-emitting layer of Embodiment 1, the electron transport auxiliary layer was not formed, and the electron transport layer material Alq₃ was deposited to 30 nm instead of 25 nm.

### Evaluation Example 1

For the organic EL devices prepared in Embodiments (Em.) 1 to 16 and Comparative Examples (Comp. Ex.) 1 to 3, a driving voltage, an emission wavelength, and a current efficiency were measured at a current density of 10 mA/cm², respectively, and the results are shown in Table 2 below.

TABLE 2

| | | | | Electron | | | |
|---|---|---|---|---|---|---|---|
| | | | | transport | | | |
| | Light-emitting layer material | | | auxiliary | Driving | Emission | Current |
| | | | Weight ratio | layer | voltage | peak | efficiency |
| Sample | A | B | (A:B:DS-405) | material (C) | (V) | (nm) | (cd/A) |
| Em. 1 | 1 | ADN | 50:50:5 | 1 | 4.2 | 456 | 7.4 |
| Em. 2 | 2 | ADN | 50:50:5 | 2 | 4.1 | 452 | 7.0 |
| Em. 3 | 3 | ADN | 50:50:5 | 3 | 4.1 | 450 | 7.8 |
| Em. 4 | 4 | ADN | 50:50:5 | 4 | 3.8 | 452 | 7.5 |
| Em. 5 | 5 | ADN | 50:50:5 | 5 | 3.7 | 455 | 7.2 |
| Em. 6 | 6 | ADN | 50:50:5 | 6 | 4.0 | 452 | 8.0 |
| Em. 7 | 7 | ADN | 50:50:5 | 7 | 4.0 | 455 | 8.0 |
| Em. 8 | 8 | ADN | 50:50:5 | 8 | 3.9 | 455 | 7.7 |
| Em. 9 | 9 | ADN | 50:50:5 | 9 | 4.1 | 452 | 7.6 |
| Em. 10 | 10 | ADN | 50:50:5 | 10 | 4.1 | 455 | 7.5 |
| Em. 11 | 11 | ADN | 50:50:5 | 11 | 3.7 | 455 | 8.1 |
| Em. 12 | 12 | ADN | 50:50:5 | 12 | 3.7 | 458 | 7.1 |
| Em. 13 | 13 | ADN | 50:50:5 | 13 | 3.8 | 455 | 7.6 |
| Em. 14 | 14 | ADN | 50:50:5 | 14 | 4.2 | 456 | 7.8 |
| Comp. | — | ADN | 0:100:5 | 1 | 4.8 | 458 | 6.2 |
| Ex. 1 | | | | | | | |
| Comp. | 1 | — | 100:0:5 | — | 5.0 | 455 | 6.0 |
| Ex. 2 | | | | | | | |
| Comp. | — | ADN | 0:100:5 | — | 5.2 | 457 | 6.4 |
| Ex. 3 | | | | | | | |

Referring to Table 2, it was appreciated that the blue organic EL devices of Embodiments 1 to 14 according to the present invention in which one of the plurality of hosts in the light-emitting layer includes a material the same as a material included in the electron transport auxiliary layer achieved excellent performance in terms of the driving voltage, the emission peak and the current efficiency as compared to Comparative Examples 1 to 3.

1. An organic electroluminescent device comprising:
an anode;
a cathode disposed opposing the anode; and
an organic layer disposed between the anode and the cathode and comprising a hole transport region, a light-emitting layer, and an electron transport region sequentially disposed on the anode,
wherein the electron transport region comprises an electron transport auxiliary layer, an electron transport layer and an electron injection layer sequentially disposed on the light-emitting layer,
the light-emitting layer comprises a plurality of hosts and dopants, and
one of the plurality of hosts comprises a material the same as a material of the electron transport auxiliary layer.

2. The organic electroluminescent device of claim 1, wherein the electron transport auxiliary layer satisfies the following Relational Expression 3:

|HOMO_{aETL}|>|HOMO_{EL}| [Relational Expression 3]
wherein
HOMO_{aETL} is a HOMO energy level of the electron transport auxiliary layer, and
HOMO_{EL} is a HOMO energy level of the light-emitting layer.

3. The organic electroluminescent device of claim 2, wherein a difference between an absolute value of the HOMO energy level of the electron transport auxiliary layer and an absolute value of the HOMO energy level of the light-emitting layer is in a range of greater than 0 eV to 1.0 eV or less.

4. The organic electroluminescent device of claim 1, wherein the electron transport auxiliary layer satisfies the following Relational Expression 4:

|LUMO_{ETL}|>|LUMO_{aETL}|>|HOMO_{EL}| [Relational Expression 4]
wherein
LUMO_{ETL} is a LUMO energy level of the electron transport layer,
LUMO_{aETL} is a LUMO energy level of the electron transport auxiliary layer, and
LUMO_{EL} is a LUMO energy level of the light-emitting layer.

5. The organic electroluminescent device of claim 4, wherein a difference between an absolute value of the LUMO energy level of the electron transport auxiliary layer and an absolute value of the LUMO energy level of the electron transport layer is in a range of greater than 0 eV to 1.0 eV or less.

6. The organic electroluminescent device of claim 4, wherein a difference between an absolute value of the LUMO energy level of the electron transport auxiliary layer and an absolute value of the LUMO energy level of the light-emitting layer is in a range of greater than 0 eV to 1.0 eV or less.

7. The organic electroluminescent device of claim 1, wherein a material of the electron transport auxiliary layer comprises a compound comprising one or more moiety selected from moieties represented by the following Chemical Formulas 1 and 2: 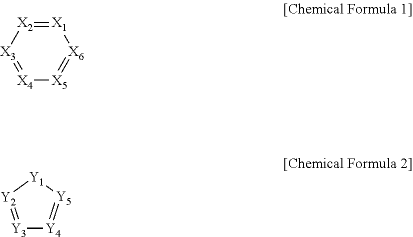
wherein in Chemical Formulas 1 and 2,
X₁ to X₆ are the same as or different from each other, each independently being N or C(R₁), wherein at least one of X₁ to X₆ is N, and when C(R₁) is plural in number, the plurality of R₁ are the same as or different from each other,
Y₁ to Y₅ are the same as or different from each other, each independently being N or C(R₂), wherein at least one of Y₁ to Y₅ is N, and when C(R₂) is plural in number, the plurality of R₂ are the same as or different from each other,
R₁ and R₂ are the same as or different from each other, each independently being selected from: hydrogen, deuterium, a halogen group, a cyano group, a nitro group, an amino group, a C₁ to C₄₀ alkyl group, a C₂ to C₄₀ alkenyl group, a C₂ to C₄₀ alkynyl group, a C₃ to C₄₀ cycloalkyl group, a heterocycloalkyl group having 3 to 40 nuclear atoms, a C₆ to C₆₀ aryl group, a heteroaryl group having 5 to 60 nuclear atoms, a C₁ to C₄₀ alkyloxy group, a C₆ to C₆₀ aryloxy group, a C₁ to C₄₀ alkylsilyl group, a C₆ to C₆₀ arylsilyl group, a C₁ to C₄₀ alkylboron group, a C₆ to C₆₀ arylboron group, a C₆ to C₆₀ arylphosphine group, a C₆ to C₆₀ arylphosphine oxide group and a C₆ to C₆₀ arylamine group, or forming a fused ring with an adjacent group, and
the alkyl group, the alkenyl group, the alkynyl group, the aryl group, the heteroaryl group, the aryloxy group, the alkyloxy group, the cycloalkyl group, the heterocycloalkyl group, the arylsilyl group, the alkylsilyl group, the alkylboron group, the arylboron group, the phosphine group, and the phosphine oxide group of R₁ and R₂ are each independently substituted or unsubstituted with one or more substituents of: hydrogen, deuterium, a halogen group, a cyano group, a nitro group, a C₁ to C₄₀ alkyl group, a C₂ to C₄₀ alkenyl group, a C₂ to C₄₀ alkynyl group, a C₃ to C₄₀ cycloalkyl group, a heterocycloalkyl group having 3 to 40 nuclear atoms, a C₆ to C₆₀ aryl group, a heteroaryl group having 5 to 60 nuclear atoms, a C₁ to C₄₀ alkyloxy group, a C₆ to C₆₀ aryloxy group, a C₁ to C₄₀ alkylsilyl group, a C₆ to C₆₀ arylsilyl group, a C₁ to C₄₀ alkylboron group, a C₆ to C₆₀ arylboron group, a C₆ to C₆₀ arylphosphine group, a C₆ to C₆₀ arylphosphine oxide group and a C₆ to C₆₀ arylamine group, and when the substituents are plural in number, the substituents are the same as or different from each other.

8. The organic electroluminescent device of claim 7, wherein the compound comprising one or more moiety is a compound represented by any one of the following Chemical Formulas 4 to 6: 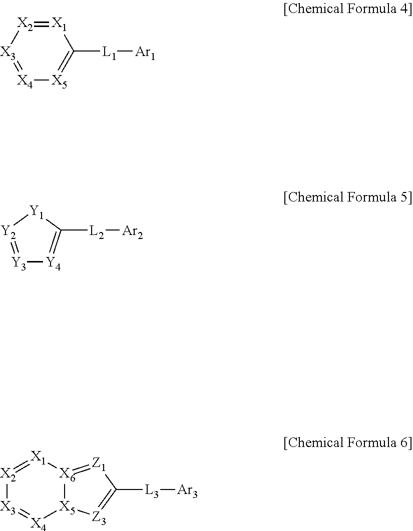
wherein in Chemical Formulas 4 to 6,
X₁ to X₆ and Y₁ to Y₄ are the same as those defined in claim 7, respectively,
Z₁ and Z₃ are the same as or different from each other, each independently being N or C(R₃), wherein at least one of Z₁ and Z₃ is N, and when C(R₃) is plural in number, the plurality of R₃ are the same as or different from each other,
L₁ to L₃ are the same as or different from each other, each independently being a single bond, or being selected from: a C₆ to C₁₈ arylene group and a heteroarylene group having 5 to 18 nuclear atoms,
Ar₁ to Ar₃ are the same as or different from each other, each independently being a substituent selected from substituents represented by the following Chemical Formulas S1 to S9: 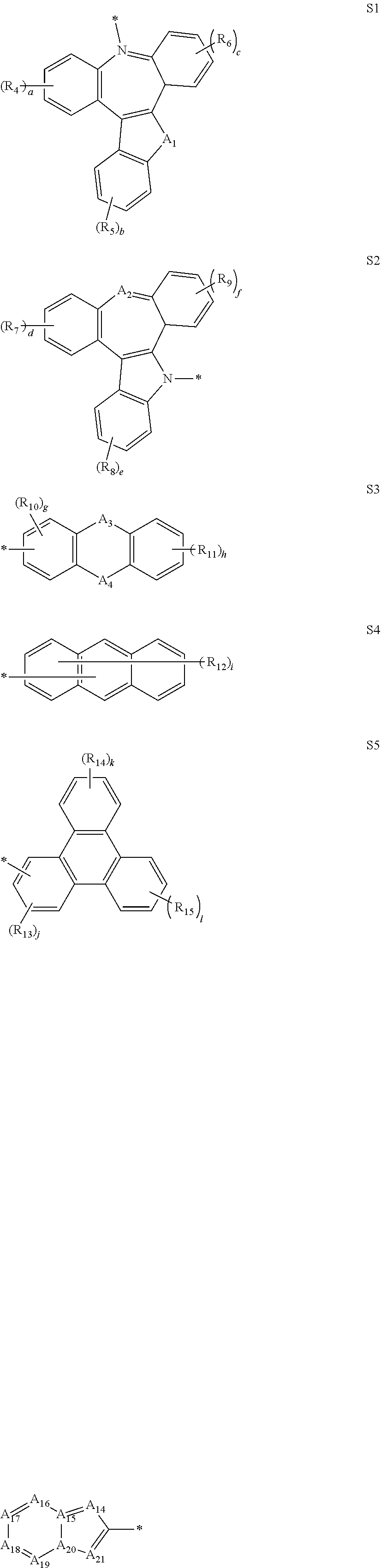 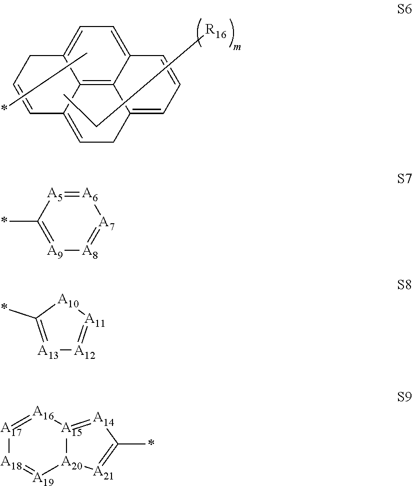
in Chemical Formulas S1 to S9,
A₁ and A₂ are N or CR₁₇,
A₃ and A₄ are the same as or different from each other, each independently being a single bond, or being selected from: NR₁₈, O, S, and CR₁₉R₂₀, wherein a case where both of A₃ and A₄ are single bonds is excluded,
A₅ to A₉ are N or CR₂₁, wherein at least one of A₅ to A₉ is N, and when CR₂₁ is plural in number, the plurality of R₂₁ are the same as or different from each other,
A₁₀ to A₁₃ are N or CR₂₂, wherein at least one of A₁₀ to A₁₃ is N, and when CR₂₂ is plural in number, the plurality of R₂₂ are the same as or different from each other,
A₁₄ to A₂₁ are N or CR₂₃, wherein at least one of A₁₄ to A₂₁ is N, and when CR₂₃ is plural in number, the plurality of R₂₃ are the same as or different from each other,
a, b, c, d, e, f, h, k, and 1 are each an integer in a range of 0 to 4;
g and j are each an integer in a range of 0 to 3,
i and m are each an integer in a range of 0 to 9,
R₃ to R₂₃ are the same as or different from each other, each independently being selected from: hydrogen, deuterium, a halogen group, a cyano group, a nitro group, an amino group, a C₁ to C₄₀ alkyl group, a C₂ to C₄₀ alkenyl group, a C₂ to C₄₀ alkynyl group, a C₃ to C₄₀ cycloalkyl group, a heterocycloalkyl group having 3 to 40 nuclear atoms, a C₆ to C₆₀ aryl group, a heteroaryl group having 5 to 60 nuclear atoms, a C₁ to C₄₀ alkyloxy group, a C₆ to C₆₀ aryloxy group, a C₁ to C₄₀ alkylsilyl group, a C₆ to C₆₀ arylsilyl group, a C₁ to C₄₀ alkylboron group, a C₆ to C₆₀ arylboron group, a C₆ to C₆₀ arylphosphine group, a C₆ to C₆₀ arylphosphine oxide group and a C₆ to C₆₀ arylamine group, or forming a fused ring with an adjacent group, and
the alkyl group, the alkenyl group, the alkynyl group, the aryl group, the heteroaryl group, the aryloxy group, the alkyloxy group, the cycloalkyl group, the heterocycloalkyl group, the arylsilyl group, the alkylsilyl group, the alkylboron group, the arylboron group, the phosphine group, and the phosphine oxide group of R₃ to R₂₃ are each independently substituted or unsubstituted with one or more substituents of: hydrogen, deuterium, a halogen group, a cyano group, a nitro group, a C₁ to C₄₀ alkyl group, a C₂ to C₄₀ alkenyl group, a C₂ to C₄₀ alkynyl group, a C₃ to C₄₀ cycloalkyl group, a heterocycloalkyl group having 3 to 40 nuclear atoms, a C₆ to C₆₀ aryl group, a heteroaryl group having 5 to 60 nuclear atoms, a C₁ to C₄₀ alkyloxy group, a C₆ to C₆₀ aryloxy group, a C₁ to C₄₀ alkylsilyl group, a C₆ to C₆₀ arylsilyl group, a C₁ to C₄₀ alkylboron group, a C₆ to C₆₀ arylboron group, a C₆ to C₆₀ arylphosphine group, a C₆ to C₆₀ arylphosphine oxide group and a C₆ to C₆₀ arylamine group, and when the substituents are plural in number, the substituents are the same as or different from each other.

9. The organic electroluminescent device of claim 8, wherein the compound represented by any one of Chemical Formulas 4 to 6 is selected from the following Chemical Formulas A-1 to A-16: 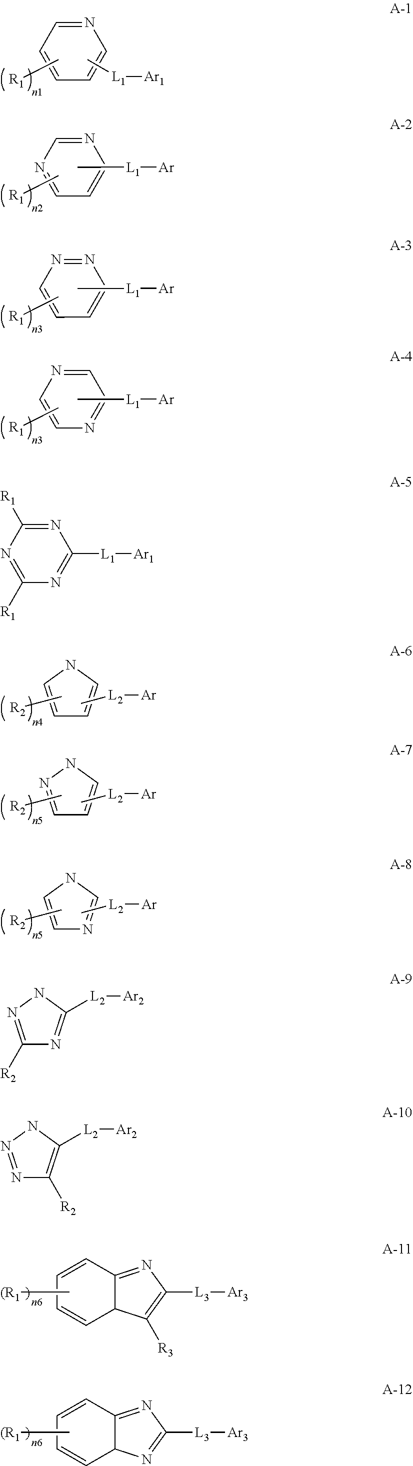 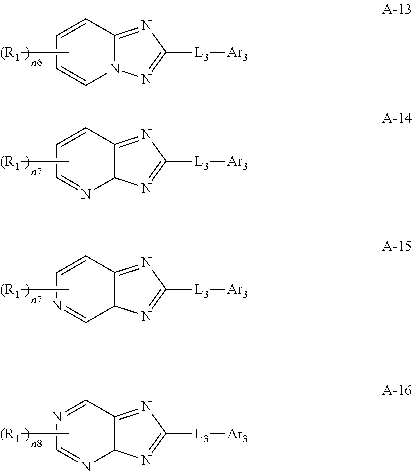
wherein in Chemical Formulas A-1 to A-16,
L₁ to L₃, Ar₁ to Ar₃, and R₃ are the same as those defined in claim 8, respectively,
R₁ and R₂ are the same as or different from each other, each independently being selected from: hydrogen, deuterium, a halogen group, a cyano group, a nitro group, an amino group, a C₁ to C₄₀ alkyl group, a C₂ to C₄₀ alkenyl group, a C₂ to C₄₀ alkynyl group, a C₃ to C₄₀ cycloalkyl group, a heterocycloalkyl group having 3 to 40 nuclear atoms, a C₆ to C₆₀ aryl group, a heteroaryl group having 5 to 60 nuclear atoms, a C₁ to C₄₀ alkyloxy group, a C₆ to C₆₀ aryloxy group, a C₁ to C₄₀ alkylsilyl group, a C₆ to C₆₀ arylsilyl group, a C₁ to C₄₀ alkylboron group, a C₆ to C₆₀ arylboron group, a C₆ to C₆₀ arylphosphine group, a C₆ to C₆₀ arylphosphine oxide group and a C₆ to C₆₀ arylamine group, or forming a fused ring with an adjacent group, and
the alkyl group, the alkenyl group, the alkynyl group, the aryl group, the heteroaryl group, the aryloxy group, the alkyloxy group, the cycloalkyl group, the heterocycloalkyl group, the arylsilyl group, the alkylsilyl group, the alkylboron group, the arylboron group, the phosphine group, and the phosphine oxide group of R₁ and R₂ are each independently substituted or unsubstituted with one or more substituents of: hydrogen, deuterium, a halogen group, a cyano group, a nitro group, a C₁ to C₄₀ alkyl group, a C₂ to C₄₀ alkenyl group, a C₂ to C₄₀ alkynyl group, a C₃ to C₄₀ cycloalkyl group, a heterocycloalkyl group having 3 to 40 nuclear atoms, a C₆ to C₆₀ aryl group, a heteroaryl group having 5 to 60 nuclear atoms, a C₁ to C₄₀ alkyloxy group, a C₆ to C₆₀ aryloxy group, a C₁ to C₄₀ alkylsilyl group, a C₆ to C₆₀ arylsilyl group, a C₁ to C₄₀ alkylboron group, a C₆ to C₆₀ arylboron group, a C₆ to C₆₀ arylphosphine group, a C₆ to C₆₀ arylphosphine oxide group and a C₆ to C₆₀ arylamine group, and when the substituents are plural in number, the substituents are the same as or different from each other,
n₁ and n₆ are each an integer in a range of 0 to 4,
n₂, n₃, n₄, and n₇ are each an integer in a range of 0 to 3, and
n₅ and n₈ are each an integer in a range of 0 to 2.

10. The organic electroluminescent device of claim 7, wherein the compound represented by any one of Chemical Formulas 4 to 6 is selected from the following Chemical Formulas B-1 to B-9: 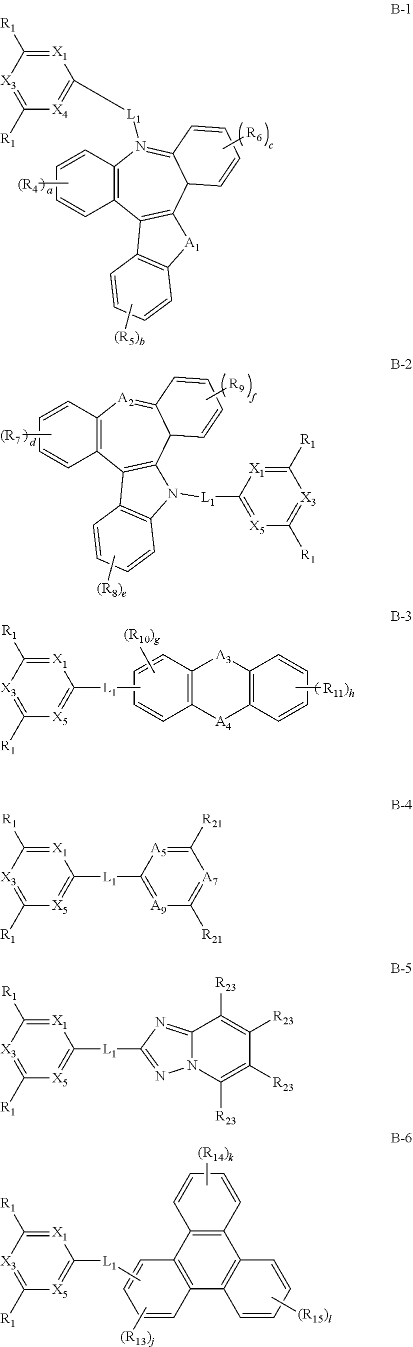 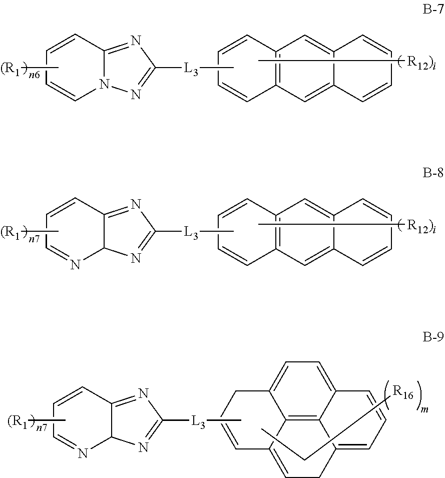
wherein in Chemical Formulas B-1 to B-9,
X₁, X₃, X₅, and R₁ are the same as those defined in claim 7, respectively,
L₁ and L₃ are the same as or different from each other, each independently being a single bond, or being selected from: a C₆ to C₁₈ arylene group and a heteroarylene group having 5 to 18 nuclear atoms,
A₁ and A₂ are N or CR₁₇,
A₃ and A₄ are the same as or different from each other, each independently being a single bond, or being selected from: NR₁₈, O, S, and CR₁₉R₂₀, wherein a case where both of A₃ and A₄ are single bonds is excluded,
A₅, A₇, and A₉ are N or CR₂₁, wherein at least one of A₅, A₇, and A₉ is N, and when CR₂₁ is plural in number, the plurality of R₂₁ are the same as or different from each other,
a, b, c, d, e, f, h, k, and 1 are each an integer in a range of 0 to 4;
g and j are each an integer in a range of 0 to 3,
i and m are each an integer in a range of 0 to 9,
n₆ is an integer in a range of 0 to 4,
n₇ is an integer in a range of 0 to 3,
R₄ to R₂₃ are the same as or different from each other, each independently being selected from: hydrogen, deuterium, a halogen group, a cyano group, a nitro group, an amino group, a C₁ to C₄₀ alkyl group, a C₂ to C₄₀ alkenyl group, a C₂ to C₄₀ alkynyl group, a C₃ to C₄₀ cycloalkyl group, a heterocycloalkyl group having 3 to 40 nuclear atoms, a C₆ to C₆₀ aryl group, a heteroaryl group having 5 to 60 nuclear atoms, a C₁ to C₄₀ alkyloxy group, a C₆ to C₆₀ aryloxy group, a C₁ to C₄₀ alkylsilyl group, a C₆ to C₆₀ arylsilyl group, a C₁ to C₄₀ alkylboron group, a C₆ to C₆₀ arylboron group, a C₆ to C₆₀ arylphosphine group, a C₆ to C₆₀ arylphosphine oxide group and a C₆ to C₆₀ arylamine group, or forming a fused ring with an adjacent group, and
the alkyl group, the alkenyl group, the alkynyl group, the aryl group, the heteroaryl group, the aryloxy group, the alkyloxy group, the cycloalkyl group, the heterocycloalkyl group, the arylamine group, the alkylsilyl group, the alkylboron group, the arylboron group, the phosphine group, and the phosphine oxide group of R₄ to R₂₃ are each independently substituted or unsubstituted with one or more substituents of: hydrogen, deuterium, a halogen group, a cyano group, a nitro group, a C₁ to C₄₀ alkyl group, a C₂ to C₄₀ alkenyl group, a C₂ to C₄₀ alkynyl group, a C₃ to C₄₀ cycloalkyl group, a heterocycloalkyl group having 3 to 40 nuclear atoms, a C₆ to C₆₀ aryl group, a heteroaryl group having 5 to 60 nuclear atoms, a C₁ to C₄₀ alkyloxy group, a C₆ to C₆₀ aryloxy group, a C₁ to C₄₀ alkylsilyl group, a C₆ to C₆₀ arylsilyl group, a C₁ to C₄₀ alkylboron group, a C₆ to C₆₀ arylboron group, a C₆ to C₆₀ arylphosphine group, a C₆ to C₆₀ arylphosphine oxide group and a C₆ to C₆₀ arylamine group, and when the substituents are plural in number, the substituents are the same as or different from each other.

11. The organic electroluminescent device of claim 7, wherein the compound comprising the least one moiety is a compound represented by any one of the following Chemical Formulas 1 to 14:

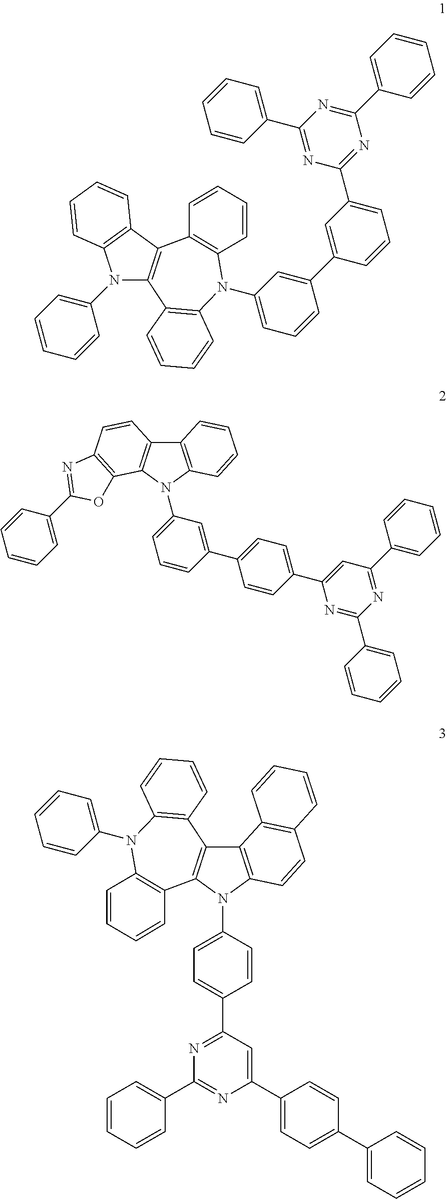 [SMILES: c1ccc(-c2nc(-c3ccccc3)nc(-c3cccc(-c4cccc(N5c6ccccc6-c6c(n(-c7ccccc7)c7ccccc67)-c6ccccc65)c4)c3)n2)cc1 ; c1ccc(-c2cc(-c3ccc(-c4cccc(-n5c6ccccc6c6ccc7nc(-c8ccccc8)oc7c65)c4)cc3)nc(-c3ccccc3)n2)cc1 ; c1ccc(-c2ccc(-c3cc(-c4ccc(-n5c6c(c7c8ccccc8ccc75)-c5ccccc5N(c5ccccc5)c5ccccc5-6)cc4)nc(-c4ccccc4)n3)cc2)cc1]

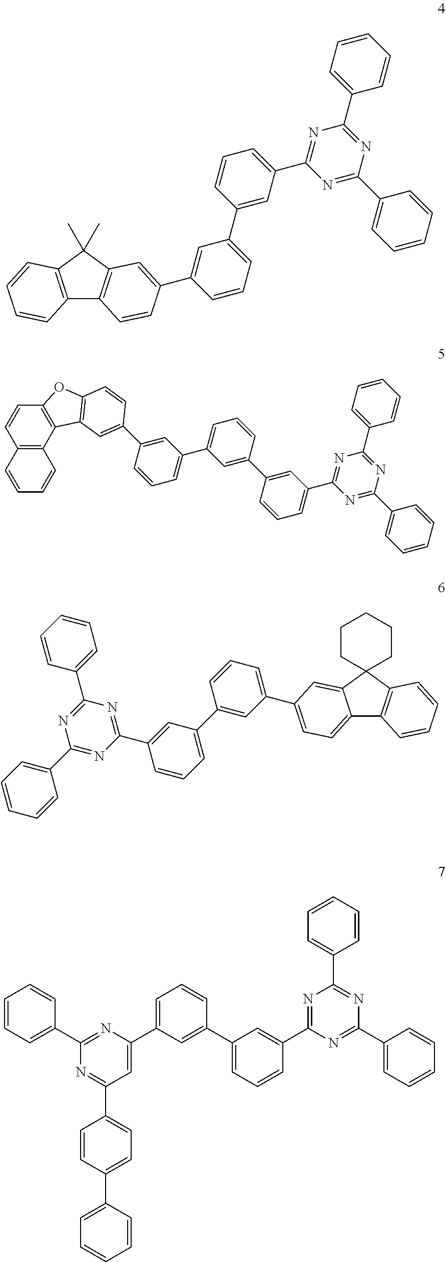 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-c4cccc(-c5cccc(-c6ccc7oc8ccc9ccccc9c8c7c6)c5)c4)c3)n2)cc1 ; c1ccc(-c2nc(-c3ccccc3)nc(-c3cccc(-c4cccc(-c5ccc6c(c5)C5(CCCCC5)c5ccccc5-6)c4)c3)n2)cc1 ; c1ccc(-c2ccc(-c3cc(-c4cccc(-c5cccc(-c6nc(-c7ccccc7)nc(-c7ccccc7)n6)c5)c4)nc(-c4ccccc4)n3)cc2)cc1]

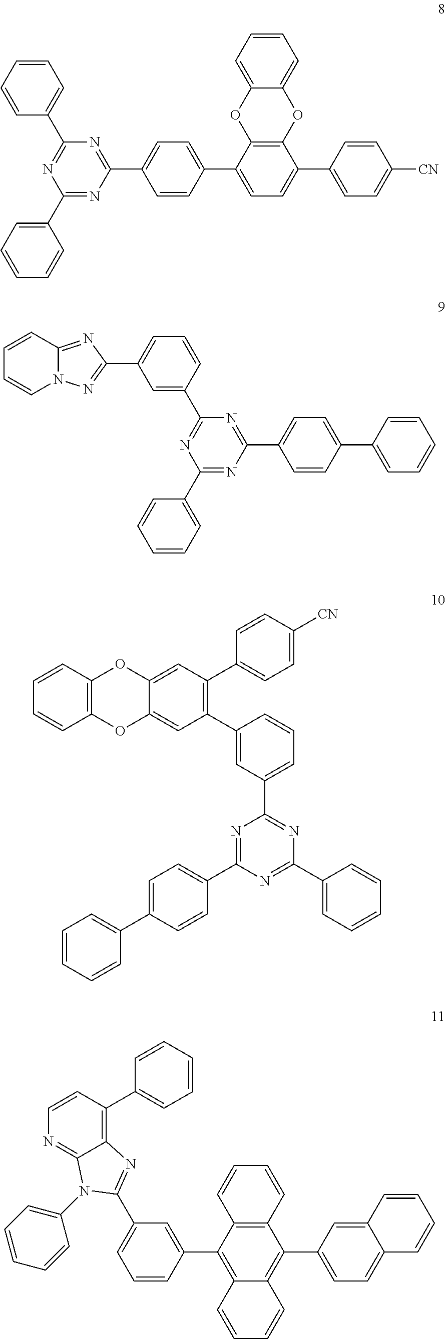 [SMILES: N#Cc1ccc(-c2ccc(-c3ccc(-c4nc(-c5ccccc5)nc(-c5ccccc5)n4)cc3)c3c2Oc2ccccc2O3)cc1 ; c1ccc(-c2ccc(-c3nc(-c4ccccc4)nc(-c4cccc(-c5nc6ccccn6n5)c4)n3)cc2)cc1 ; N#Cc1ccc(-c2cc3c(cc2-c2cccc(-c4nc(-c5ccccc5)nc(-c5ccc(-c6ccccc6)cc5)n4)c2)Oc2ccccc2O3)cc1 ; c1ccc(-c2ccnc3c2nc(-c2cccc(-c4c5ccccc5c(-c5ccc6ccccc6c5)c5ccccc45)c2)n3-c2ccccc2)cc1]

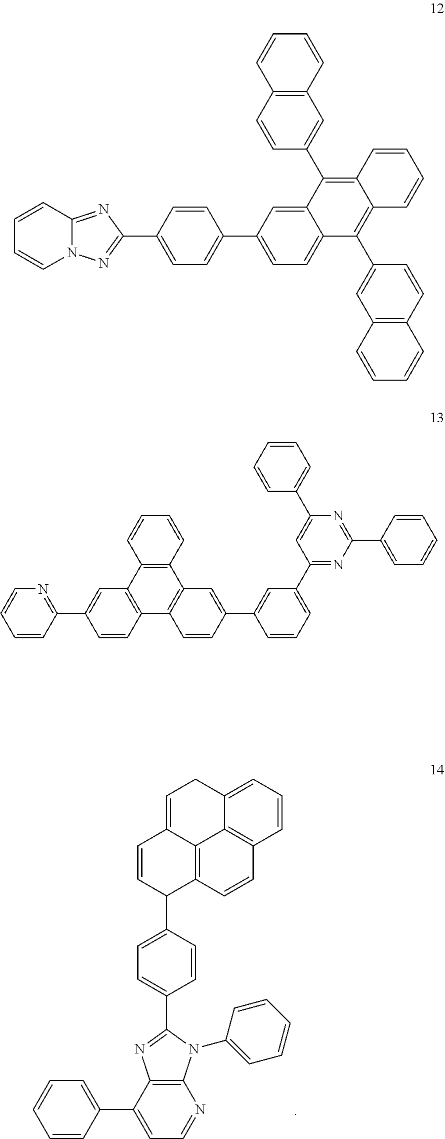 [SMILES: c1ccc2cc(-c3c4ccccc4c(-c4ccc5ccccc5c4)c4cc(-c5ccc(-c6nc7ccccn7n6)cc5)ccc34)ccc2c1 ; c1ccc(-c2cc(-c3cccc(-c4ccc5c6ccc(-c7ccccn7)cc6c6ccccc6c5c4)c3)nc(-c3ccccc3)n2)cc1 ; C1=CC(c2ccc(-c3nc4c(-c5ccccc5)ccnc4n3-c3ccccc3)cc2)c2ccc3cccc4c3c2C1=CC4]

12. The organic electroluminescent device of claim 1, wherein a content of hosts the same as the material of the electron transport auxiliary layer from among the plurality of hosts is in a range of 30 to 90 percent by weight (wt %) with respect to the total amount of entire hosts.

13. The organic electroluminescent device of claim 1, wherein the plurality of hosts comprises:
a first host the same as the material of the electron transport auxiliary layer; and
a second host different from the first host and satisfying the following Relational Expressions 1 and 2:

|LUMOₕₒₛₜ₋₁|>|LUMOₕₒₛₜ₋₂| [Relational Expression 1]

|HOMOₕₒₛₜ₋₁|>|HOMOₕₒₛₜ₋₂| [Relational Expression 2]
wherein in Relational Expressions 1 and 2,
LUMOₕₒₛₜ₋₁ is a LUMO energy level of the first host,
LUMOₕₒₛₜ₋₂ is a LUMO energy level of the second host,
HOMOₕₒₛₜ₋₁ is a HOMO energy level of the first host, and
HOMOₕₒₛₜ₋₂ is a HOMO energy level of the second host.

14. The organic electroluminescent device of claim 13, wherein a difference between an absolute value of the LUMO energy level of the second host and an absolute value of the LUMO energy level of the first host is in a range of greater than 0 eV to 1.0 eV or less, and
a difference between an absolute value of the HOMO energy level of the second host and an absolute value of the HOMO energy level of the first host is in a range of greater than 0 eV to 1.0 eV or less.

15. The organic electroluminescent device of claim 13, wherein a use ratio of the first host and the second host is in a range of 30:70 to 90:10 by weight.

16. The organic electroluminescent device of claim 1, wherein the dopant is in a range of more than 0 parts by weight to 20 parts by weight or less, with respect to 100 parts by weight of the plurality of hosts.

17. The organic electroluminescent device of claim 1, wherein the light-emitting layer is formed by co-depositing the plurality of hosts.

18. The organic electroluminescent device of claim 1, wherein the hole transport region comprises at least one of: a hole injection layer, a hole transport layer and a hole transport auxiliary layer.
